(19) United States
(12) Patent Application Publication
(10) Pub. No.: US 2007/0277810 A1
(43) Pub. Date: Dec. 6, 2007

(54) Solar Panel

(75) Inventor: Andrew Stock, Magill (AU)

Correspondence Address: WOODCOCK WASHBURN LLP, CIRA CENTRE, 12TH FLOOR, 2929 ARCH STREET, PHILADELPHIA, PA, 19104-2891, US

(73) Assignee: Origin Energy Solar Pty Ltd, Adelaide (AU)

(21) Appl. No.: 10/586,941

(22) PCT Filed: Jan. 21, 2005
(86) PCT No.: PCT/AU05/00069

§ 371 Date: May 22, 2007

(30) Foreign Application Priority Data
Jan. 23, 2004 (AU) 2004900329

(51) Int. Cl. H01L 31/042

(52) U.S. Cl. 126/569; 136/246; 29/890.033

(57) ABSTRACT

The invention provides a solar panel having a panel front and a panel back, comprising an array of solar cells and an element comprising a visually distinguishable feature. Each of the solar cells has a front and a back, wherein at least the front is capable of converting at least a portion of solar light incident thereon into electrical energy. There are spacings between at least some of the solar cells. The element comprising the visually distinguishable feature is located at at least one position selected from the group consisting of between the panel back and the panel front, on the panel front, on the panel back, at the panel front, and at the panel back, such that the visually distinguishable feature is at least partially distinguishable on viewing the panel front. The nature of the visually distinguishable feature and/or the location of the element relative to the solar cells does not completely prevent solar light incident on the panel front from being incident on at least a portion of the array.

### TECHNICAL FIELD

The present invention relates to a solar panel having a visually distinguishable feature.

### BACKGROUND OF THE INVENTION

Solar energy has long been considered as a renewable alternative to the energy generated from fossil fuels that is predominantly used today. Solar energy offers various advantages over more conventional power sources, and represents a clean source for generating electricity. Furthermore, solar cells do not need to be replenished with non-renewable fuels. Instead, they are powered by the effectively limitless energy from the sun.

Solar energy conversion modules that convert sunlight into electrical energy typically use photovoltaic or photoelectric cells, which convert the solar energy directly into electrical energy. The amount of energy generated by a cell is directly related to the amount of solar energy the cell absorbs; the amount of energy the cell absorbs is a function of both the size or surface area of the cell and the intensity or brightness of the sunlight that strikes the cell.

It is convenient to locate arrays of solar cells near to where the energy will be used, in order to minimise the losses associated with transmission of electricity over long distances. Most electricity is used in or near cities, towns or other human habitation, and consequently such arrays are often highly visible. A disadvantage of many solar panels is that, since they are designed to absorb the maximum amount of visible light, they appear as dark and unattractive to the eye.

There is a need for a solar panel that is aesthetically pleasing to the eye, or that may be used for purposes of marketing and advertising.

### OBJECT OF THE INVENTION

It is an object of the present invention to overcome or substantially ameliorate the above disadvantage. It is a further object to at least partially satisfy the abovementioned need.

### SUMMARY OF THE INVENTION

In a first aspect of the invention there is provided a solar panel having a panel front and a panel back comprising:
an array of solar cells, each of said solar cells having a front and a back, wherein at least the front is capable of converting at least a portion of solar light incident thereon into electrical energy, there being spacings between at least some of the solar cells, and
an element comprising a visually distinguishable feature at at least one position selected from the group consisting of between the panel back and the panel front, on the panel front, on the panel back, at the panel front, and at the panel back, such that the visually distinguishable feature is at least partially distinguishable on viewing the panel front, and wherein the nature of the visually distinguishable feature and/or the location of the element relative to the solar cells does not completely prevent solar light incident on the panel front from being incident on at least a portion of the array.

Throughout the specification the expression “visually distinguishable feature” may be taken as meaning, for example, one or more of a design, a colour, a pattern, a decoration, a picture, a drawing, a sketch, an etching, a marking, a layout, a sketch, a brand, an advertisement, a notice, a sign, a name, a seal, an insignia, a portrait, a scene, a cartoon, a caricature, an icon, a signature, a photograph, an image, a logo, at least one letter, at least one number, at least one word, a calendar, a label, a trademark, a plan, a map, at least one marking or other visually distinguishable feature or a combination of two or more of these.

The nature of the visually distinguishable feature and/or the location of the element relative to the solar cells may be such that the amount of solar light incident on the array relative to the amount of solar light incident on the panel front is greater than about 50%. The amount of solar light incident on the array relative to the amount of solar light incident on the panel front may be greater than about 55, 60, 65, 70, 75, 80, 85, 90 or 95% and maybe about 50, 55, 60, 65, 70, 75, 80, 85, 90, 91, 92, 93, 94, 95, 96, 97, 98, 99, 99.5 or 99.9%. The element may be removable from the solar panel. There may be an encapsulant between the cells, and the encapsulant may be at least partially transparent. The array may be disposed on a support panel, or between support panels, said support panel(s) being transparent. The support panel(s) may be made of glass, polymethylmethacrylate, polycarbonate, fluoropolymer (for example Tefzel or Teflon), PET, Tedlar, PE or epoxy or some other suitable transparent.

In a first embodiment, at least some of the solar cells are Sliver® cells, as described in WO02/45143, the contents of which are incorporated herein by cross-reference.

In a second embodiment the backs of at least some of the solar cells are capable of converting at least a portion of solar light incident thereon into electrical energy and either there is a reflector located between the array and the panel back or the panel back comprises a reflector. The reflector may be capable of reflecting at least part of the solar light incident on the solar panel towards the backs of at least some of the solar cells. The reflector may be, or may approximate, a Lambertian reflector, a diffuse reflector or a light scattering reflector.

In a third embodiment the visually distinguishable feature is at least partially distinguishable through the array on viewing the panel front or the panel back. The panel back may comprise the element comprising the visually distinguishable feature, or the element comprising the visually distinguishable feature may be located between the panel back and the array. The element may be a reflector and may be, or may approximate, a Lambertian reflector, a diffuse reflector or a light scattering reflector. The element may be disposed on or integral with the reflector. The element may be at least partially transparent.

In a fourth embodiment the element is located between the solar cells of the array. The element may comprise an encapsulant. The element may for example comprise transparent coloured material, optionally having different colours in different regions of the array.

In a fifth embodiment either the element is located between the array and the panel front, or the panel front comprises the element. In this embodiment the nature of the visually distinguishable feature and/or the location of the element relative to the solar cells does not completely prevent solar light incident on the panel front from being incident on at least a portion of the array.

In a sixth embodiment the element comprises at least one activatable element the appearance of which is capable of being changed by application of a stimulus, for example an electrical, thermal, optical or magnetic stimulus. The stimulus may be supplied from a source external to the solar panel, or it may be provided at least in part by the array of solar cells. For example the element may comprise one or more LEDs or LCD panels, and the visually distinguishable feature may be capable of being changed electronically.

In a seventh embodiment the solar panel additionally comprises means to change the visually distinguishable feature. The means to change the visually distinguishable feature may comprise means to change the visually distinguishable feature physically, mechanically, electrically, thermally, optically or magnetically, and may comprise, for example, at least one electrical terminal, at least one heating or cooling element or at least one magnet.

In an eighth embodiment there is provided a solar panel comprising:
an array of solar cells, each of said solar cells having a front and a back, wherein at least the front is capable of converting at least a portion of solar light incident thereon into electrical energy, there being spacings between at least some of the solar cells, and
an element comprising a visually distinguishable feature and disposed such that the visually distinguishable feature is at least partially distinguishable through the array of solar cells.
   The array and the element may be substantially parallel. The element may be disposed behind the array.

In a ninth embodiment there is provided a solar panel comprising:
an array of solar cells, each of said solar cells having a front and a back, wherein both the front and the back are capable of converting at least a portion of solar light incident thereon into electrical energy, there being spacings between at least some of the solar cells, and
a reflector disposed so as to be capable of reflecting at least part of the solar light incident on the solar panel towards the backs of at least some of the solar cell,
   wherein the reflector comprises a visually distinguishable feature such that the visually distinguishable feature is at least partially distinguishable through the array of solar cells.
   The array and the reflector may be substantially parallel. The reflector may be disposed behind the array.

In a tenth embodiment there is provided a solar panel comprising:
an array of solar cells, each of said solar cells having a front and a back, wherein both the front and the back are capable of converting at least a portion of solar light incident thereon into electrical energy, there being spacings between at least some of the solar cells,
a reflector disposed so as to be capable of reflecting at least part of the solar light incident on the solar panel towards the backs of at least some of the solar cell, and
an element comprising a visually distinguishable feature such that the visually distinguishable feature is at least partially distinguishable through the array of solar cells wherein the element is located between the array and the reflector, and whereby at least a portion of light incident on the solar panel is reflected by the reflector towards the backs of at least some of the solar cells.
   The array, the reflector and the element may be substantially parallel. The element may be located behind the array, and the reflector may be located behind the element.

In an eleventh embodiment there is provided a solar panel comprising:
an array of solar cells, each of said solar cells having a front and a back, wherein at least the front is capable of converting at least a portion of solar light incident thereon into electrical energy, there being spacings between at least some of the solar cells, and
an element comprising a visually distinguishable feature, said element being located in at least some of the spacings.

In a twelfth embodiment there is provided a solar panel comprising:
an array of solar cells, each of said solar cells having a front and a back, wherein both the front and the back are capable of converting at least a portion of solar light incident thereon into electrical energy, there being spacings between at least some of the solar cells,
an element comprising a visually distinguishable feature, said element being located in at least some of the spacings, and

a reflector disposed so as to be capable of reflecting at least part of the solar light incident on the solar panel towards the backs of at least some of the solar cell.

The array and the reflector may be substantially parallel. The element may be at least partially transparent. The reflector may be located behind the array.

In a thirteenth embodiment there is provided a solar panel comprising:
an array of solar cells, each of said solar cells having a front and a back, wherein at least the front is capable of converting at least a portion of solar light incident thereon into electrical energy, there being spacings between at least some of the solar cells, and
an element comprising a visually distinguishable feature such that at least a portion of light incident on the element passes therethrough to the fronts of at least some of the solar cells.
   The array and the element may be substantially parallel. The array may be located behind the element. The element may be at least partially transparent.

In a fourteenth embodiment there is provided a solar panel comprising:
an array of solar cells, each of said solar cells having a front and a back, wherein both the front and the back are capable of converting at least a portion of solar light incident thereon into electrical energy, there being spacings between at least some of the solar cells,
an element comprising a visually distinguishable feature such that at least a portion of light incident on the element passes therethrough to the fronts of at least some of the solar cells, and
a reflector disposed so as to be capable of reflecting at least part of the solar light incident on the solar panel towards the backs of at least some of the solar cell.

The array, the element and the reflector may be substantially parallel. The array may be located between the element and the array. The array may be located behind the element and the reflector may be located behind the array. The element may be at least partially transparent.

In a second aspect of the invention there is provided a solar panel comprising an array of solar cells, each of said solar cells having a front and a back, wherein at least the front is capable of converting at least a portion of solar light incident thereon into electrical energy, and wherein there are spacings between at least some of the solar cells whereby the arrangement of the solar cells in the array embodies a visually distinguishable feature.

For example, since the solar cells appear dark, there may be regions of the array in which the spacings between solar cells are relatively small, these regions appearing relatively dark, and other regions of the array in which the spacings between solar cells are relatively large, these regions appearing relatively pale. The arrangement of such regions may be such as to embody a visually distinguishable feature.

In an embodiment, the solar panel comprises a reflector located so that it is capable of reflecting at least part of the solar light incident thereon towards at least some of the solar cells of the array. The reflector may be, or may approximate, a Lambertian reflector, a diffuse reflector or a light scattering reflector. The backs of at least some of the solar cells may be capable of converting at least a portion of solar light incident thereon into electrical energy.

In another embodiment, the solar panel and a reflector are located so that the reflector is capable of reflecting at least a part of the solar light incident thereon towards at least some of the solar cells of the array. The reflector may be, or may approximate, a Lambertian reflector, a diffuse reflector or a light scattering reflector. The backs of at least some of the solar cells may be capable of converting at least a portion of solar light incident thereon into electrical energy.

In another embodiment there is provided a solar panel comprising:
an array of solar cells, each of said solar cells having a front and a back, wherein both the front and the back are capable of converting at least a portion of solar light incident thereon into electrical energy, and wherein there are spacings between at least some of the solar cells whereby the arrangement of the solar cells in the array embodies a visually distinguishable feature, and
a reflector located so that it is capable of reflecting at least part of solar light incident on the solar panel towards the backs of at least some of the solar cells of the array.
   The array and the reflector may be substantially parallel. The reflector may be located behind the array.

In a third aspect of the invention there is provided a combination for conversion of solar energy comprising:
an array of solar cells, each of said solar cells having a front and a back, wherein at least the front is capable of converting at least a portion of solar light incident thereon into electrical energy, there being spacings between at least some of the solar cells, and said array having an array front and an array back, and
an element comprising a visually distinguishable feature at at least one position selected from the group consisting of in front of the array front, at the array front, at the array back or behind the array back, such that the visually distinguishable feature is at least partially distinguishable on viewing the combination, and wherein the nature of the visually distinguishable feature and/or the location of the element relative to the solar cells does not completely prevent solar light incident on the combination from being incident on at least a portion of the array.

The nature of the visually distinguishable feature and/or the location of the element relative to the solar cells may be such that the amount of solar light incident on the array relative to the amount of solar light incident on the combination is greater than about 50%. The amount of solar light incident on the array relative to the amount of solar light incident on the combination may be greater than about 55, 60, 65, 70, 75, 80, 85, 90 or 95% and may be about 50, 55, 60, 65, 70, 75, 80, 85, 90, 91, 92, 93, 94, 95, 96, 97, 98, 99, 99.5 or 99.9%. There may be an encapsulant between the cells, and the encapsulant may be at least partially transparent. The array may be disposed on a support panel, or between support panels, said support panel(s) being transparent. The support panel(s) may be made of glass, polymethylmethacrylate, polycarbonate, fluoropolymer (for example Tefzel or Teflon), PET, Tedlar, PE or epoxy or some other suitable transparent.

In a first embodiment, at least some of the solar cells are Sliver® cells, as described in WO02/45143, the contents of which are incorporated herein by cross-reference.

In a second embodiment the backs of at least some of the solar cells are capable of converting at least a portion of solar light incident thereon into electrical energy and there is a reflector located so that it is capable of reflecting at least part of the solar light incident on the solar panel towards the backs of at least some of the solar cells. The reflector may be, or may approximate, a Lambertian reflector, a diffuse reflector or a light scattering reflector.

In a third embodiment the visually distinguishable feature is at least partially distinguishable through the array on viewing the combination. The element comprising the visually distinguishable feature may be located either at the array back or behind the array back. The element may comprise a reflector. The element may be disposed on or integral with the reflector.

In a fourth embodiment the element comprising the visually distinguishable feature is located between the solar cells of the array. The element may comprise an encapsulant. The element may for example comprise transparent coloured material, optionally having different colours in different regions of the array.

In a fifth embodiment the element is located either at the array front or in front of the array front. In this embodiment the nature of the visually distinguishable feature and/or the location of the element relative to the solar cells does not completely prevent solar light incident on the element from being incident on at least a portion of the array.

In a sixth embodiment the element comprises at least one activatable element the appearance of which is capable of being changed by application of a stimulus, for example an electrical, thermal, optical or magnetic stimulus. The stimulus may be supplied from a source external to the solar panel, or it may be provided at least in part by the array of solar cells. For example the element may comprise one or more LEDs or LCD panels, and the visually distinguishable feature may be capable of being changed electronically.

In a seventh embodiment the combination additionally comprises means to change the visually distinguishable feature. The means to change the visually distinguishable feature may comprise means to change the visually distinguishable feature physically, mechanically, electrically, thermally, optically or magnetically, and may comprise, for example, at least one electrical terminal, at least one heating or cooling element or at least one magnet.

In a fourth aspect of the invention there is provided a process for making a solar panel having a panel front and a panel back, said process comprising locating:
an array of solar cells, each of said solar cells having a front and a back, wherein at least the front is capable of converting at least a portion of solar light incident thereon into electrical energy, there being spacings between at least some of the solar cells, and
an element comprising a visually distinguishable feature, such that the element is located at at least one position selected from the group consisting of between the panel back and the panel front, on the panel front, on the panel back, at the panel front, and at the panel back, and such that the visually distinguishable feature is at least partially distinguishable on viewing the panel front, and wherein the nature of the visually distinguishable feature and/or the location of the visually distinguishable feature relative to the solar cells does not completely prevent solar light incident on the panel front from being incident on at least a portion of the array.

In a first embodiment, at least some of the solar cells are Sliver® cells, as described in WO02/45143, the contents of which are incorporated herein by cross-reference.

In a second embodiment the backs of at least some of the solar cells are capable of converting at least a portion of solar light incident thereon into electrical energy and the process comprises locating a reflector such that the reflector is capable of reflecting at least part of the solar light incident on the solar panel towards the backs of at least some of the solar cells. The reflector may be, or may approximate, a Lambertian reflector, a diffuse reflector or a light scattering reflector.

In a third embodiment the locating is such that the visually distinguishable feature is at least partially distinguishable through the array on viewing the panel front or the panel back. The panel back may comprise the element comprising the visually distinguishable feature, or the element comprising the visually distinguishable feature may be located between the panel back and the array. The element may be a reflector, and may be, or may approximate, a Lambertian reflector, a diffuse reflector or a light scattering reflector. The element may be disposed on or integral with the reflector. The element may be at least partially transparent.

In a fourth embodiment the element is located between the solar cells of the array. The element may comprise an encapsulant. The element may for example comprise transparent coloured material, optionally having different colours in different regions of the array.

In a fifth embodiment either the element is located between the array and the panel front, or the panel front comprises the element. In this embodiment the nature of the visually distinguishable feature and/or the location of the element relative to the solar cells does not completely prevent solar light incident on the panel front from being incident on at least a portion of the array.

In a sixth embodiment the element comprises at least one activatable element the appearance of which is capable of being changed by application of a stimulus, for example an electrical, thermal, optical or magnetic stimulus. The stimulus may be supplied from a source external to the solar panel, or it may be provided at least in part by the array of solar cells. For example the element may comprise one or more LEDs or LCD panels, and the visually distinguishable feature may be capable of being changed electronically.

In a fifth aspect of the invention there is provided a process for making a solar panel comprising the step of arranging a plurality of solar cells in an array, each of said solar cells having a front and a back, wherein at least the front is capable of converting at least a portion of solar light incident thereon into electrical energy, and wherein there are spacings between at least some of the solar cells whereby the arrangement of the solar cells in the array embodies a visually distinguishable feature.

In an embodiment the process additionally comprises the step of locating the solar panel and a reflector such that the reflector is capable of reflecting at least part of the solar light incident on the solar panel towards at least some of the solar cells of the array. The backs of at least some of the solar cells may be capable of converting at least a portion of solar light incident thereon into electrical energy.

In a sixth aspect of the invention there is provided a process for making a combination for conversion of solar energy, said process comprising locating:
an array of solar cells, each of said solar cells having a front and a back, wherein at least the front is capable of converting at least a portion of solar light incident thereon into electrical energy, there being spacings between at least some of the solar cells, and said array having an array front and an array back, and
an element comprising a visually distinguishable feature,
   such that the element is located at at least one position selected from the group consisting of in front of the array front, at the array front, at the array back or behind the array back, and such that the visually distinguishable feature is at least partially distinguishable on viewing the panel front, and wherein the nature of the visually distinguishable feature and/or the location of the visually distinguishable feature relative to the solar cells does not completely prevent solar light incident on the combination from being incident on at least a portion of the array.

In a first embodiment, at least some of the solar cells are Sliver® cells, as described in WO02/45143, the contents of which are incorporated herein by cross-reference.

In a second embodiment the backs of at least some of the solar cells are capable of converting at least a portion of solar light incident thereon into electrical energy and the process comprises locating a reflector such that the reflector is capable of reflecting at least part of the solar light incident on the solar panel towards the backs of at least some of the solar cells. The reflector may be, or may approximate, a Lambertian reflector, a diffuse reflector or a light scattering reflector.

In a third embodiment the locating is such that the visually distinguishable feature is at least partially distinguishable through the array on viewing the combination. The element comprising the visually distinguishable feature may be located either at the array back or behind the array back. The element may comprise a reflector. The element may be disposed on or integral with the reflector.

In a fourth embodiment the element comprising the visually distinguishable feature is located between the solar cells of the array. The element may comprise an encapsulant. The element may for example comprise transparent coloured material, optionally having different colours in different regions of the array.

In a fifth embodiment the element is located either at the array front or in front of the array front. In this embodiment the nature of the visually distinguishable feature and/or the location of the element relative to the solar cells does not completely prevent solar light incident on the element from being incident on at least a portion of the array.

In a sixth embodiment the element comprises at least one activatable element the appearance of which is capable of being changed by application of a stimulus, for example an electrical, thermal, optical or magnetic stimulus. The stimulus may be supplied from a source external to the array, or it may be provided at least in part by the array of solar cells. For example the element may comprise one or more LEDs or LCD panels, and the visually distinguishable feature may be capable of being changed electronically.

There is also provided a solar panel, or a combination for conversion of solar energy, when made by any of the processes of the invention.

In a seventh aspect of the invention there is provided a solar cell having a front and a back, wherein at least the front is capable of converting at least a portion of solar light incident thereon into electrical energy, or an array of such solar cells, when used in a solar panel, or a combination, according to the invention.

### DETAILED DESCRIPTION OF THE INVENTION

The present invention relates to a solar panel, or a combination for conversion of solar energy, having a visually distinguishable feature. As described herein, it has been found that a solar panel, or combination, comprising solar cells having a front and a back, wherein at least the front is capable of converting a portion of solar light incident thereon into electrical energy, may be constructed with substantial spacings between the solar cells while retaining adequate light capture efficiency. The spacings between the solar cells may thus be utilised in order to provide the solar panel or combination with a visually distinguishable feature in order to provide decoration, identification, advertising, information, or for any other suitable purpose. The element of the panel or combination to which the visually distinguishable feature is capable of being applied may be located either between the solar cells of the array or behind the array of the solar cells or in front of the array of the solar cells, or it may be manifested in the arrangement of the solar cells in the array, these alternatives being described in several of the aspects and embodiments of this specification. The visually distinguishable feature is at least partially distinguishable when viewing the front of the solar panel or the combination.

In this specification, when an element of the solar panel or combination is referred to as “comprising a visually distinguishable feature”, the element either comprises a visually distinguishable feature or is capable of comprising a visually distinguishable feature when an appropriate stimulus is applied to that element. The stimulus may be for example electrical, thermal, optical or magnetic, and may be either provided by an external source or provided at least in part by the solar array. An example is a solar panel with a reflector comprising one or more LEDs or LCD or video display panels, wherein the visually distinguishable feature may be created or changed electronically. Alternatively the element comprising the visually distinguishable feature may be separate from the reflector, as described elsewhere herein. If the element comprising the visually distinguishable feature comprises a plurality of panels, each of which is changeable electronically, the panels may be connected to a control unit, which converts an input signal to a plurality of output signals, each of which is fed to one of the panels so that the images on the panels provide a single visually distinguishable feature. The control unit may comprise a computer or some other signal processing device, and may also comprise means to output the output signals to the panels, for example an output manifold. The control unit may be a multi-screen processor, for example ComputerWall® from RGB Spectrum or VN-2400 Networked Processor from Visionetwork™. The control unit may use appropriate software for multi-screen processing, for example C-THROUGH™ for Windows® (which supports Imagestar™ and PICBLOC™ videowall processors) or Commander™ control software from Electrosonic Ltd. (Hawley Mill, Hawley Mill Road, Dartford, Kent DA27SY, United Kingdom). It may be a video matrix processor, for sending different images to the different panels, or it may be a video wall controller/server/video server for controlling an array of screens to show different parts of the same image (i.e. make a single composite image). For example the input signal may be multiplexed using a multiplexer, for example in order to create a single visually distinguishable feature over the panels. In another example the reflector comprises thermally sensitive components and the visually distinguishable feature may depend on the temperature in different regions of the solar panel.

The element may be a component or a part of the solar panel. It may be integral with the solar panel. The element may be for example the panel back or the panel front or the array or some other element of the solar panel. The element may be located between the panel back and the panel front, on the panel front, on the panel back, at the panel front, or at the panel back. Thus the element may be attached to (i.e. “on”) the panel back or the panel front, or it may be at a location which represents the panel front or panel back (i.e. it may be “at” the panel front or panel back). Alternatively it may be at a location intermediate (i.e. “between”) the panel front and the panel back.

The visually distinguishable feature may be reflective and/or absorbing towards light. Part of the visually distinguishable feature may be reflective and part may be absorbing. In particular the visually distinguishable feature or a part thereof may reflect light which is absorbable by the solar cells.

In this specification, the term “transparent” refers to a material that is substantially transparent to light at a wavelength to which the solar cells are responsive (for silicon about 350 nm to about 1200 nm). “Substantially” in this context refers to transmission of greater than about 80% of incident light at a wavelength to which the solar cells are responsive. The transmission may be greater than about 85%, 90%, 95% or 98%, and may be about 80, 85, 90, 95, 96, 97, 98, 99, 99.5 or 99.9%.

A Lambertian reflector is a diffuse reflector which obeys Lambert's Law. Lambert's Law states, that for such a reflector, the radiance of the reflected light is directly proportional to the cosine of the angle, with respect to the direction of maximum radiance, from which the reflector is viewed. A diffuse reflector is a reflecting surface that scatters radiation that is incident on it, thus producing diffuse reflection.

It is theorised that in a solar panel, or a combination. according to this invention wherein the solar panel or combination comprises a reflector, incident light that passes through spaces between the cells may be reflected by the reflector. It may then be absorbed by the rear (backs) of the cells, or may reflect from the front support panel onto the cells, and only a portion of the light will escape. In a representative solar panel or combination, when about 50% of the area of the array is occupied by solar cells, about 84% of light incident on the array may be captured, and when about 33% of the area of the array is occupied by solar cell, about 74% of light incident on the array may be captured. A portion of light that is not captured may be used to transmit a visually distinguishable feature to an observer.

If the solar cells are small, the visually distinguishable feature may appear to be unobscured when the solar panel or combination is viewed from a distance. The distance may depend on the spacings between the solar cells, on the dimensions of the solar cells and on the nature of the visually distinguishable feature, and may be greater than about 1 meter, or it may be greater than about 2, 3, 4, 5, 10, 20, 50, 100, 200, 500 or 1000 meters, and may be between about 1 and 1000 meters, or between about 2 and 500 meters or between about 5 and 100 meters or between about 10 and 50 meters, and may be about 1, 2, 3, 4, 5, 10, 20, 50, 100, 200, 500 or 1000 meters, or it may be less than about 1 meter. The spacings between solar cells may be the same or they may be different. The mean ratio between the spacing between solar cells and the width of a solar cell may be between about 0.5 and 5, or between about 1 and 4 or between about 1 and 3, and may be about 0.5, 1, 1.5, 2, 2.5, 3, 3.5, 4, 4.5 or 5. The spacing between solar cells may be between about 0.1 and 20 mm, and may be between about 0.1 and 10, 0.1 and 5, 0.1 and 2, 0.1 and 1, 0.5 and 5, 0.5 and 2, 0.8 and 2, 0.8 and 1.5, 0.5 and 20, 1 and 20, 5 and 20, 10 and 20, 0.5 and 10, 1 and 10 or 2 and 5 mm, and may be about 0.1, 0.2, 0.3, 0.4, 0.5, 0.6, 0.7, 0.8, 0.9, 1, 1.1, 1.2, 1.3, 1.4, 1.5, 1.6, 1.7, 1.8, 1.9, 2, 2.5 3, 3.5, 4, 4.5, 5, 6, 7, 8, 9, 10, 11, 12, 13, 14, 15, 16, 17, 18, 19 or 20 mm, or may be greater than 20 mm. The spacings may be all the same, or may be different, or some may be the same and some may be different. The ratio of the area of an array to the area of a single solar cell within said array may be greater than about 100, 200, 500, 1000, 2000, 5000 or 10000, and may be between about 100 and about 100000, or between about 200 and about 50000 or between about 500 and about 10000 or between about 1000 and about 5000, and may be about 100, 200, 500, 1000, 2000, 5000, 10000, 20000, 50000 or 100000. There may be more than about 50 solar cells in an array, or more than about 100, 200, 500, 1000, 2000, 5000 or 10000, and may be between about 50 and 100000, or between about 100 and about 100000, or between about 200 and about 50000 or between about 500 and about 10000 or between about 1000 and about 5000, and may be about 50, 100, 200, 500, 1000, 2000, 5000, 10000, 20000, 50000 or 100000.

The solar cells in the array may be electrically interconnected in series, in parallel, or in a combination of series and parallel. The electrical connections may be small in cross-section so as to absorb only a small amount of light. The electrical connections may be made of a transparent electrically conductive material, for example indium-tin-oxide or other oxide materials based on cadmium, gallium, copper, zinc, indium and/or tin, or may be based on a conductive polymer such as polyaniline.

The solar cells may be rectangular, square, round, elliptical, oval, parallelogram, polygonal, triangular or some other shape, and may be a mixture of shapes. They may be all the same size or they may be different sizes, or some may be the same size and some may be different sizes. The arrangement of different shapes and/or of different sizes of solar cells may embody a visually distinguishable feature according to the present invention.

Sliver® cells, described in WO02/45143, are particularly suitable for use as solar cells in the solar panels or combinations of the present invention. Sliver® cells are long and narrow (commonly about 0.75-1.5 mm wide, about 50-150 mm long and about 0.03-0.1 mm thick), and light incident on either the front or the back thereof may be converted into electrical energy. Due to their dimensions, the cells commonly do not obscure any entire aspect of a visually distinguishable feature viewed through an array of such cells, and consequently a visually distinguishable feature is commonly distinguishable through such an array. When viewed from a distance, the visually distinguishable feature commonly appears unobscured. A feature of Sliver® cells is that they may be assembled into an array with substantial spaces between individual cells, and still display an acceptable level of solar collection efficiency. This feature renders Sliver® cells particularly suitable for use in the present invention, since in several embodiments of the invention the visually distinguishable feature may be readily distinguished through the spaces between cells or between the cells. The width of the solar cells of the invention may be between about 0.2 and 10 mm, or between about 0.3 and 5 mm or between about 0.4 and 4 mm or between about 0.5 and 3 mm or between about 0.5 and 2 mm, and may be about 0.2, 0.3, 0.4, 0.5, 0.6, 0.7, 0.8, 0.9, 1, 1.5, 2, 2.5, 3, 3.5, 4, 4.5, 5, 6, 7, 8, 9 or 10 mm. The length of the solar cells of the invention may be between about 10 and 300 mm, or between about 20 and 250 mm or between about 30 and 200 mm or between about 40 and 150 mm or between about 50 and 150 mm, and may be about 10, 20, 30, 40,50, 60, 70, 80, 90, 100, 110, 120, 140, 160, 180, 200, 250 or 300 mm. The thickness of the solar cells of the invention may be between about 0.025 and 0.25 mm, or between about 0.025 and 1 mm, 0.025 and 0.05 mm, 0.05 and 0.25 mm, 0.1 and 0.25 mm, or 0.05 and 0.1 mm, and may be about 0.025, 0.03, 0.04, 0.05, 0.06, 0.07, 0.08, 0.09, 0.1, 0.11, 0.12, 0.13, 0.14, 0.15, 0.16, 0.17, 0.18, 0.19, 0.2, 0.21, 0.21, 0.22, 0.23, 0.24 or 0.25 mm. The thickness of the solar cells may be such that they are at least partially transparent, that is, at least a portion of light incident on the front of the cell passes through the solar cell. The proportion of light incident on the front of the cell that passes through the solar cell may be between about 0 and 80%, or between about 0 and 70, 0 and 60, 0 and 50, 0 and 40, 0 and 30, 0 and 20, 0 and 10, 0 and 5, 10 and 80, 20 and 80, 50 and 80, 10 and 60, 20 and 50 or 30 and 50%, and may be about 0, 5, 10, 15, 20, 25, 30, 35, 40, 45, 50, 55, 60, 65, 70, 75 or 80%. Commonly Sliver® cells are about 1 mm wide and about 100 mm long. A solar cell that may be used in the present invention may have a p-n junction on the front and/or on the back thereof, and may have p-n junctions on both the front and the back thereof. When a solar cell is in an array as described in the present invention, it may have an electrical contact on at least one side thereof. It may have no electrical contact on the front or on the back thereof.

In some embodiments of the invention, solar cells for use in the present invention may have electrical contacts on the front and on the back, wherein the electrical contact on the front and/or on the back is capable of permitting at least a portion of the light incident thereon to pass to the solar cell. Thus for example the electrical contact may be at least partially transparent, and/or may comprise holes or spaces to permit passage of light. It may for example comprise a conductive grid or mesh.

A solar cell which may be used in the present invention may comprise:
a semiconductor strip comprising a p-type dopant or an n-type dopant and having a front, a back, a first side surface and a second side surface, wherein, in the event that the semiconductor strip comprises a p-type dopant, a first diffusion layer of an n-type conductivity has been introduced by diffusion, using a suitable dopant, into at least a portion of the front surface and at least a portion of the first side surface and, in the event that the semiconductor strip comprises an n-type dopant, a first diffusion layer of a p-type conductivity has been introduced by diffusion, using a suitable dopant, into at least a portion of the front surface and at least a portion of the first side surface;
a first metal contact in electrical contact with the first diffusion layer of the first side surface; and
a second metal contact in electrical contact with the second side surface but being electrically isolated from the first diffusion layer.

A suitable solar cell may for example comprise:
a semiconductor strip comprising a p-type dopant and having a front, a back, a first side surface and a second side surface, wherein a first diffusion layer of n-type conductivity has been introduced by diffusion, using an n-type dopant, into at least a portion of the front surface and into at least a portion of the first side surface;
a first metal contact in electrical contact with the first diffusion layer of the first side surface; and
a second metal contact in electrical contact with the second side surface but being electrically isolated from the first diffusion layer.

The semiconductor strip may be of lightly doped p-type conductivity, wherein the first diffusion layer is of heavily doped n-type conductivity, wherein a second diffusion layer of heavily doped p-type conductivity has been formed by diffusion, using a p-type dopant, into at least a portion of the second side surface and wherein the second electrical contact is in electrical contact with the second diffusion layer.

The first diffusion layer of n-type conductivity may have, in addition to the front and first side surface, also been formed into at least a portion of the back.

Another suitable solar cell may comprise:
a semiconductor strip comprising an n-type dopant and having a front, a back, a first side surface and a second side surface, wherein a first diffusion layer of p-type conductivity has been formed by diffusion, using a p-type dopant, into at least a portion of the front and into at least a portion of the first side surface;
a first metal contact in electrical contact with the first diffusion layer of the first side surface; and
a second metal contact in electrical contact with the second side surface but being electrically isolated from the first diffusion layer.

The semiconductor strip may be of lightly doped n-type conductivity, wherein the first diffusion layer is of heavily doped p-type conductivity, wherein a second diffusion layer of heavily doped n-type conductivity has been formed by diffusion, using an n-type dopant, into at least a portion of the second side surface and wherein the second electrical contact is in electrical contact with the second diffusion layer. The first diffusion layer of n-type conductivity may have, in addition to the front and first side surfaces, also been formed into at least a portion of the back.

In a solar cell suitable for use in the present invention, the semiconductor may be for example silicon, the p-dopant may be for example boron and the n-dopant may be for example phosphorus. The solar cell may comprise a textured surface provided on at least one of the front and back to reduce reflectance of light incident thereon. It may comprise an anti-reflective layer provided on at least one of the front and back to reduce reflectance of light incident thereon. It may comprise a textured surface provided on at least one of the front and back to reduce reflectance of light incident thereon and an anti-reflective layer provided on the or each textured surface to further reduce reflectance of light incident on the solar cell.

A solar panel according to the present invention may comprise a solar concentrator comprising an array of solar cells as described above and a support substrate adapted to support each of the array of solar cells in an orientation allowing at least one of is the front and the back of each of the solar cells to be exposed to solar radiation, in use, the first and second metal contacts of each of the array of solar cells being electrically interconnected. In the solar collector, the solar cells may be electrically interconnected in series, in parallel, or in a combination of series and parallel. The array of solar cells may be oriented on the support substrate such that gaps exist between adjacent solar cells. The distance of the gap between any two adjacent solar cells may be from 0.5 up to about 5 times the width of one of the solar cells. The concentrator may comprise a rear reflector spaced from the rear surfaces of the array of solar cells, the rear reflector being oriented relative to the rear surfaces of the solar cells such that, in use, incident light passing through the gaps between adjacent solar cells is reflected by the rear reflector toward the back of at least one of the solar cells. The solar concentrator may comprise a transparent superstructure having an optically reflective surface spaced from the fronts of the array of solar cells and oriented relative to the fronts of the solar cells such that, in use, incident light reflected from the solar cells or from the rear reflector and passing through the gaps between adjacent solar cells, is reflected toward the front of at least one of the solar cells. The solar concentrator may comprise a transparent superstructure located in front of the array of solar cells, a transparent substructure located on the rear side of the array of solar cells and a pottant (encapsulant) filling a space between the substructure, the array of solar cells and the superstructure.

Thus the solar concentrator may comprise:
a light-transparent superstructure having a front surface upon which light is incident in use;
an array of solar cells as described earlier herein, supported by the superstructure at positions spaced from the front, the solar cells being positioned such as to leave gaps between adjacent solar cells;
a rear reflector located at the rear of the array of solar cells and spaced therefrom, for reflecting incident light that, in use, has passed through the gaps or that has entered the solar cells and has exited them again without having been absorbed, in the direction of the back of at least one of the solar cells;
wherein each of the solar cells is oriented such that, in use, at least one of the front and rear surfaces of the solar cells is capable of receiving incident light and another of the front and rear surfaces of the cells is capable of receiving light reflected from the rear reflector.

In use, light reflected from one or more of the solar cells of the solar concentrator and the rear reflector may be reflected to a front of at least one of the solar cells by the front surface of the superstructure. The solar concentrator may further comprise a light transparent substrate on the rear side of the array of solar cells, and a polymeric or a silicone pottant material to fill a space between the superstructure, the array of solar cells and the substructure. The rear reflector may be a layer of reflective material extending through at least a portion of the rear light-transparent substrate or applied to at least a portion of a rear surface of the rear light-transparent substrate. The layer of reflective material may have a lambertian surface facing the array of cells.

The solar cells described earlier herein may be manufactured using a semiconductor wafer. The semiconductor wafer may have an upper surface, a lower surface and a plurality of slots extending from the upper surface to the lower surface and defining a plurality of semiconductor strips disposed between adjacent slots, each semiconductor strip having a front surface extending from the upper surface of the wafer to the bottom surface of the wafer, a rear surface extending from the upper surface of the wafer to the bottom surface of the wafer, a first side surface located in the same plane as and forming part of the upper surface of the wafer and a second side surface located in the same plane as and forming part of the lower surface of the wafer, wherein corresponding ends of the semiconductor strips are interconnected and form part of a portion of the wafer which surrounds the plurality of slots so as to form a protective frame.

The solar cells may be manufactured using a method which comprises the steps of:
providing a semiconductor strip having a p-type or n-type conductivity, the semiconductor strip having a front surface, a rear surface, a first side surface and a second side surface;
providing, by diffusion, using a suitable dopant, a first diffusion layer of a conductivity type opposite to the said conductivity type, into at least portion of the front surface and at least a portion of the first side surface of the semiconductor strip;
attaching a first metal contact to the first diffusion layer of the first side surface so as to be in electrical contact therewith; and
attaching a second metal contact to the second side surface so as to be in electrical contact with the second side surface but not with the first diffusion layer.

The method of manufacturing a solar cell may comprise the steps of:
providing a semiconductor strip of p-type conductivity, the semiconductor strip having a front surface, a rear surface, a first side surface and a second side surface;
providing, by diffusion, using a suitable dopant, a first diffusion layer of n-type conductivity, into at least a portion of the front surface and into at least a portion of the first side surface of the semiconductor strip;
attaching a first metal contact to the first diffusion layer of the first side surface so as to be in electrical contact therewith; and
attaching a second metal contact to the second side surface so as to be in electrical contact with the second side surface but not with the first diffusion layer.

The first metal contact to the first diffusion layer may be an ohmic contact. The second metal contact to the second side surface may be an ohmic contact.

The semiconductor strip may be of lightly doped p-type conductivity, wherein, in the step in which the first diffusion layer is provided, sufficient dopant is diffused into the first diffusion layer to yield a heavily doped n-type conductivity, the method comprising a further step wherein a second diffusion layer of heavily doped p-type conductivity is provided by diffusion, using a p-type dopant, into at least a portion of the second side surface, so that the second metal contact is in electrical contact with the second diffusion layer. The first diffusion layer of n-type conductivity may be, in addition to the front and first side surfaces, also formed into at least a portion of the rear surface.

A suitable method of manufacturing a solar cell for use in the present invention may comprise the steps of:
providing a semiconductor strip of n-type conductivity, the semiconductor strip having a front surface, a rear surface, a first side surface and a second side surface;
providing, by diffusion, using a suitable dopant, a first diffusion layer of p-type conductivity, into at least a portion of the front surface and into at least a portion of the first side surface of the semiconductor strip;
attaching a first metal contact to the first diffusion layer of the first side surface so as to be in electrical contact therewith; and
attaching a second metal contact to the second side surface so as to be in electrical contact with the second side surface but not with the first diffusion layer.

The first metal contact to the first diffusion layer may be an ohmic contact. The second metal contact to the second side surface may be an ohmic contact.

The semiconductor strip may be of lightly doped n-type conductivity, wherein, in the step in which the first diffusion layer is provided, sufficient dopant is diffused into the first diffusion layer to yield a heavily doped p-type conductivity, the method comprising a further step wherein a second diffusion layer of heavily doped n-type conductivity is formed by diffusion, using an n-type dopant, into at least a portion of the second side surface and so that the second metal contact is in electrical contact with the second diffusion layer. The first diffusion layer of heavily doped p-type conductivity may be, in addition to the front and first side surfaces, is also formed into at least a portion of the rear surface.

In order to manufacture the solar cell, a groove may be etched into a semiconductor waver. The method of etching the groove into a semiconductor wafer may include the steps of repeatedly inserting the wafer into an alkaline solution so as to expose a groove area in the surface of the wafer to the alkaline solution whilst another area on the surface of the wafer is not so exposed, and removing the wafer from the alkaline solution so as to allow the alkaline solution to drain from the wafer. The groove may be from about 5 to about 20 micrometers wide and from about 50 to about 250 micrometers deep. The semiconductor strip may be polycrystalline silicon or single crystal silicon.

The semiconductor wafer may be processed so as to form an intermediate product useful for subsequent manufacture of a solar cell, the semiconductor wafer having a substantially planar surface and a thickness dimension at right angles to said substantially planar surface. The method for processing the wafer may comprise the steps of:
creating a plurality of parallel elongated slots at least partly through said wafer, such that the combined width of said slots and width between said slots is less than the thickness of said wafer, to create a series of semiconductor strips;
separating said strips from each other; and
orienting said strips so that their faces which were previously at an angle to said substantially planar surface are exposed to form new planar surfaces.
   The method may include including the steps of selecting a strip thickness for division of the wafer into a plurality of strips, selecting a technique for cutting the wafer into said strips at an angle to said substantially planar surface, in which the combined strip thickness and width of wafer removed by the cutting is less than the thickness of the wafer, and forming deep narrow grooves in the semiconductor wafer by repeatedly inserting the wafer into an alkaline solution so as to expose a plurality of groove areas in the surface of the wafer to the alkaline solution whilst other areas on the surface of the wafer are not so exposed, and repeatedly removing the wafer from the alkaline solution so as to allow the alkaline solution to drain from the wafer.

The method of processing the semiconductor wafer having a substantially planar surface may include the steps of:
creating a plurality of parallel elongated slots through said wafer, to create a series of semiconductor strips attached at both ends to a frame portion of the semiconductor wafer; and
removing the semiconductor strips from the frame portion by cutting their ends off the frame portion.

Thus a method for producing silicon solar cells for use in the present invention may comprise the steps of:
forming a plurality of parallel slots into a silicon substrate, said slots extending at least partly through said substrate to create a series of silicon strips;
separating said strips from each other; and
fabricating solar cells from said strips. an area around the periphery of the wafer is left uncut, forming a frame, said strips being temporarily held within said frame and subsequently cut therefrom.

A laser may be used to form said slots in said wafer. Wet anisotropic etching of (110) oriented wafers may be used to form said slots. Alternatively a dicing saw may be used to form said slots in said wafer. See for example WO02/45143, the contents of which are incorporated herein by cross-reference.

A solar cell suitable for use in the present invention may comprise a semiconductor strip having a front provided with a p-n junction and a back provided with a p-n junction, the thickness of the semiconductor strip being from 50 to 250 micrometers, whereby, in use, at least a portion of light having a wavelength shorter than 1100 nm that enters the semiconductor strip from the front is absorbed in the semiconductor strip. The thickness of the semiconductor strip may be less than 100 micrometers. At least another portion of the light having a wavelength shorter than 1100 nm that enters the semiconductor strip from the front may exit the semiconductor strip at its back. The semiconductor strip may be polycrystalline silicon. The semiconductor strip may be single crystal silicon. The solar cell may comprise a first metal contact in electrical contact with the p-n junction of the front surface; and a second metal contact in electrical contact with the p-n junction of the rear surface.

The solar panel of the present invention may comprise an array of solar cells as described above and a support substrate adapted to support each of the array of solar cells in an orientation allowing at least one of the front and the back of each of the solar cells to be exposed to solar radiation, in use, the first and second metal contacts of each of the array of solar cells being electrically interconnected.

A solar cell for use in the present invention may comprise a semiconductor strip having a front, a back, a first side surface and a second side surface, wherein a p-n junction is provided on each of the front and the back, a first metal contact in electrical contact with the p-n junction of the front surface, and a second metal contact in electrical contact with the p-n junction of the rear surface. The semiconductor strip may be polycrystalline silicon. The semiconductor strip may be single crystal silicon.

A solar panel, or combination, displaying a visually distinguishable feature according to the invention may have a solar energy conversion efficiency that is not substantially lower than that of a solar panel or combination that differs from it only in that no visually distinguishable feature is displayed. The ratio of the solar energy conversion efficiency of a solar panel, or combination, displaying a visually distinguishable feature according to the invention to the solar energy conversion efficiency of a solar panel or combination that differs from it only in that no visually distinguishable feature is displayed may be between about 0.7 and 1.0 or about 0.8 and 1.0 or between about 0.85 and 1.0 or between about 0.9 and 1.0 or between about 0.95 and 1.0 or between about 0.97 and 1.0, and may be about 0.7, 0.8, 0.85, 0.9, 0.95, 0.96, 0.97, 0.98, 0.99 or 1.0. The array may be planar or curved or may be some other shape.

The visually distinguishable feature of the present invention may be suitable for the purposes of advertising or marketing or for identifying the solar panel in case of theft, or it may be decorative, or it may be capable of conveying information. It will be understood that a plurality of solar panels or combinations according to the invention may be located together, and that each may have a portion of a visually distinguishable feature in such a manner that, when viewed together, an entire visually distinguishable feature may be distinguished. The solar panel, or combination, of the present invention may have slightly lower solar conversion efficiency than a comparable solar panel, or combination, with no visually distinguishable feature. However use of a visually distinguishable feature provides substantial aesthetic benefits.

### BRIEF DESCRIPTION OF THE DRAWINGS

A preferred form of the present invention will now be described by way of example with reference to the accompanying drawings wherein:

FIG. 1 is a diagrammatic representation of a cross-section of a portion of a solar panel according to the present invention;

FIG. 2a is an illustration of the plan view of a solar panel according to the invention, having a feature which is visually distinguishable through an array of solar cells;

FIG. 2b is an illustration of the cross-section of a solar panel according to the invention, having a feature which is visually distinguishable through an array of solar cells;

FIG. 2c is an illustration of the plan view of a combination for conversion of solar energy according to the invention, having a feature which is visually distinguishable through an array of solar cells;

FIG. 2d is an illustration of the cross-section of a combination for conversion of solar energy according to the invention, having a feature which is visually distinguishable through an array of solar cells;

FIG. 3 is a diagrammatic representation of a solar panel according to the present invention wherein the element is a reflector comprising a visually distinguishable feature;

FIG. 3a is a diagrammatic representation of a combination for conversion of solar energy according to the present invention wherein the element is a reflector comprising a visually distinguishable feature;

FIG. 4a is a diagrammatic representation of a solar panel according to the present invention wherein the element comprising the visually distinguishable feature is located between a reflector and the array;

FIG. 4b is a diagrammatic representation of a solar panel according to the present invention wherein the element located between a reflector and the array comprises LEDs which may be used to display a visually distinguishable feature;

FIG. 4c is a diagrammatic representation of a combination for conversion of solar energy according to the present invention wherein the element comprising the visually distinguishable feature is located between a reflector and the array;

FIG. 4d is a diagrammatic representation of a combination for conversion of solar energy according to the present invention wherein the element located between a reflector and the array comprises LEDs which may be used to display a visually distinguishable feature;

FIG. 5 is a diagrammatic representation of a solar panel according to the present invention wherein the element comprising the visually distinguishable feature is located between the cells of the array;

FIG. 5a is a diagrammatic representation of a combination for conversion of solar energy according to the present invention wherein the element comprising the visually distinguishable feature is located between the cells of the array;

FIG. 6 is a diagrammatic representation of a solar panel according to the present invention wherein the array is located between the element which comprises a visually distinguishable feature and a reflector;

FIG. 6a is a diagrammatic representation of a combination for conversion of solar energy according to the present invention wherein the array is located between the element which comprises a visually distinguishable feature and a reflector;

FIG. 7 is a diagrammatic representation of a solar panel according to the present invention wherein a visually distinguishable feature is embodied in the arrangement of the solar cells in an array, and wherein the solar panel incorporates a reflector;

FIG. 7a is a diagrammatic representation of a solar panel according to the present invention wherein a visually distinguishable feature is embodied in the arrangement of the solar cells in an array;

FIG. 7b is a diagrammatic representation of a combination for conversion of solar energy according to the present invention wherein a visually distinguishable feature is embodied in the arrangement of the solar cells in an array, and wherein the combination incorporates a reflector;

FIG. 8 is a diagrammatic representation of a plurality of solar panels according to the present invention wherein the solar panels combine to display a single visually distinguishable feature; and

FIG. 9 is a photograph of a solar panel according to the present invention.

### DETAILED DESCRIPTION OF THE PREFERRED EMBODIMENTS

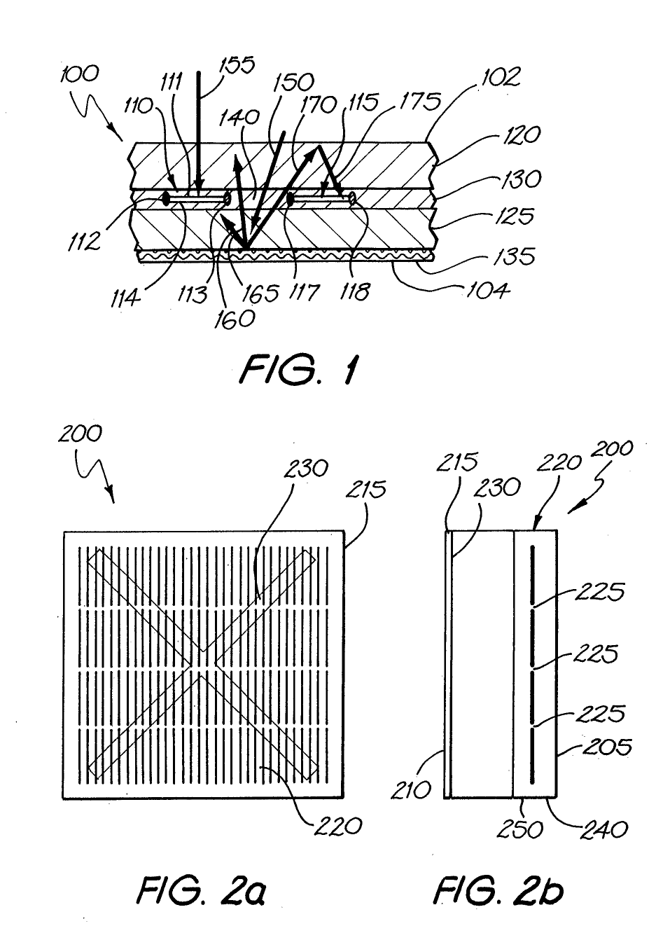

FIG. 1 is a diagrammatic representation of a cross-section of a portion of a solar panel according to the present invention, and illustrates how solar cells wherein the front and the back are each capable of converting at least a portion of solar light incident thereon into electrical energy, in combination with a Lambertian reflector, can effectively collect solar energy when there are spaces between said solar cells. Solar panel 100, a portion of which is shown in FIG. 1, has panel front 102 and panel back 104 and comprises an array of solar cells, two of which are shown in FIG. 1, those being cells 110 and 115, which have n terminals 112 and 117 respectively and p terminals 113 and 118 respectively. Each of said solar cells has a front and a back, for example front 111 and back 114 of solar cell 110, wherein the front and the back are each capable of converting at least a portion of solar light incident thereon into electrical energy. Solar cells 110 and 115 are located between front support panel 120 and back support panel 125, and are encapsulated within encapsulant 130. There are spacings between the solar cells of the array, for example spacing 140 between solar cells 110 and 115. Element 135 is a Lambertian reflector, comprising a visually distinguishable feature for example a design, and is located on panel back 104, and the visually distinguishable feature of element 135 is at least partially distinguishable on viewing panel front 102. Arrows 150 and 155 show the direction of incoming light beams, and arrows 160, 165, 170 and 175 show the directions of reflected light beams.

When light impinges on solar panel 100, incoming light beam 150 is reflected in multiple directions by element 135. Several representative beams are shown in FIG. 1, however many more beams, not shown, will reflect from element 135. Beam 160 impinges on back 114 of cell 110, and is converted by cell 110 into electrical energy. Beam 170 is reflected back through spacing 140 and passes through front panel 120. It is then reflected by panel front 102 as beam 175. Beam 175 impinges on the front of cell 115 and is converted by cell 115 into electrical energy. Beam 165 is reflected by element 135 at an angle such that it is not reflected by the panel front 102, and consequently it exits solar panel 100. Beam 165 is capable of transmitting a visually distinguishable feature of element 135 to an observer. Beam 155 does not pass through spacing 140, but impinges on front 112 of cell 110, which converts beam 155 into electrical energy. Electrical energy generated by cells 110 and 115 are transmitted to terminals 112, 113, 117 and 118, and conveyed from there by electrical conductors (not shown) to be used as required.

FIG. 2a is an illustration of the plan view of solar panel 200 having feature 230 (an “X”) which is visually distinguishable through array 220 of solar cells, and FIG. 2b is an illustration of the cross-section of solar panel 200. With reference to FIGS. 2a and 2b, solar panel 200 has panel front 205 and panel back 210. Panel 200 comprises array 220 of solar cells, each of said solar cells having a front and a back, wherein at least the front is capable of converting at least a portion of solar light incident thereon into electrical energy, there being spacings 225 between the solar cells, and element 215 comprising visually distinguishable feature 230 on the panel back, such that feature 230 is at least partially distinguishable on viewing panel front 205. Array 220 is disposed between front support panel 240 and back support panel 250, said support panels being transparent. FIG. 2 illustrates that feature 230 may be visually distinguishable through array 220.

FIG. 2c is an illustration of the plan view of combination 200c for conversion of solar energy, having feature 230c (an “X”) which is visually distinguishable through array 220c of solar cells, and FIG. 2d is an illustration of the cross-section of combination 200c. With reference to FIGS. 2c and 2d, array 220c has array front 205c and array back 210c. Combination 200c comprises array 220c of solar cells, each of said solar cells having a front and a back, wherein at least the front is capable of converting at least a portion of solar light incident thereon into electrical energy, there being spacings 225c between the solar cells, and element 215c comprising visually distinguishable feature 230c, such that feature 230c is at least partially distinguishable on viewing combination 200c. Array 220c is disposed between front support panel 240c and back support panel 250c, said support panels being transparent. FIG. 2 illustrates that feature 230c may be visually distinguishable through array 220c.

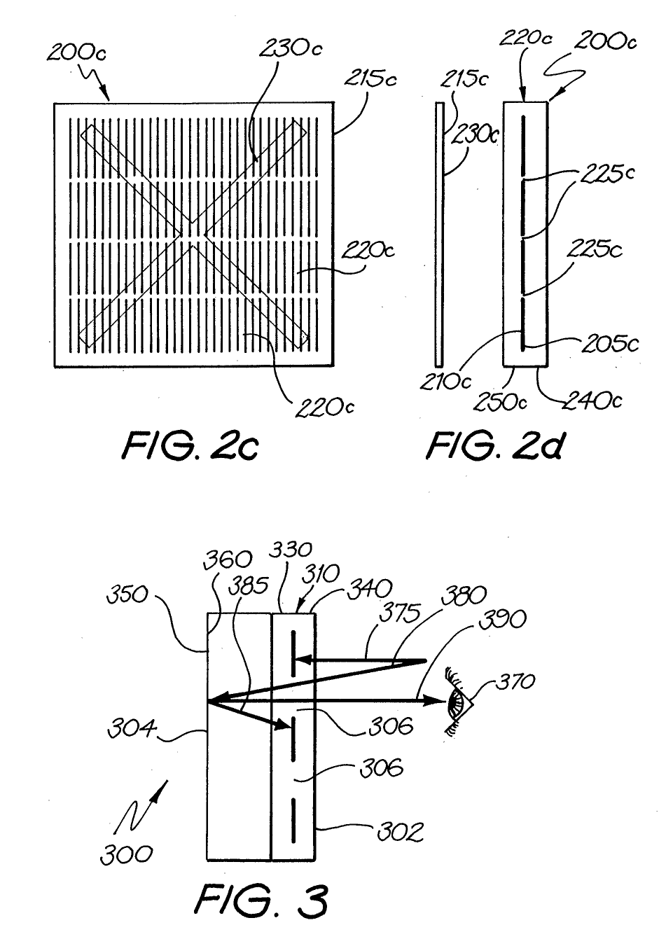

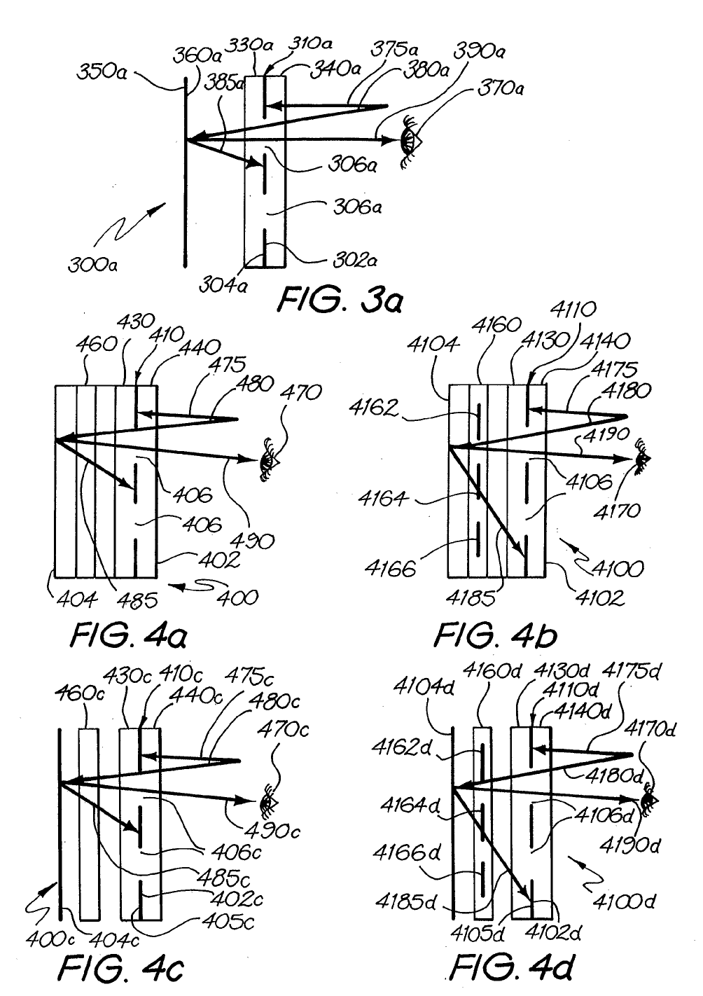

With reference to FIG. 3, solar panel 300 has panel front 302 and a panel back 304, and comprises array 310 of solar cells, each of said solar cells having a front and a back, wherein the front and the back are each capable of converting at least a portion of solar light incident thereon into electrical energy, there being spacings 306 between the solar cells. Panel back 304 comprises element 350, which comprises visually distinguishable feature 360. Element 350 is a diffuse reflector. Visually distinguishable feature 360 is at least partially distinguishable through array 310 on viewing panel front 302. Array 310 is disposed between front support panel 340 and back support panel 330, said support panels being transparent. Observer 370 is capable of distinguishing visually distinguishable feature 360 through array 310. Arrows 375, 380, 385 and 390 represent different portions of light. Thus a portion 375 of light incident on panel front 302 penetrates to array 310 and is converted by the solar cells thereof to electrical energy, and a portion 380 passes through spacing 306 to element 350, which reflects it towards back support panel 330. A portion 385 passes to the cells of array 310 and is converted to electrical energy and a portion 390 passes to observer 370, so that observer 370 distinguishes visually distinguishable feature 360.

With reference to FIG. 3a, combination 300a for conversion of solar energy comprises array 310a of solar cells, each of said solar cells having a front and a back, wherein the front and the back are each capable of converting at least a portion of solar light incident thereon into electrical energy, there being spacings 306a between the solar cells. Array 310a has array front 302a nd array back 304a. Element 350a is a diffuse reflector and comprises visually distinguishable feature 360a. Visually distinguishable feature 360a is at least partially distinguishable through array 310a on viewing combination 300a. Array 310a is disposed between front support panel 340a and back support panel 330a, said support panels being transparent. Observer 370a is capable of distinguishing visually distinguishable feature 360a through array 310a. Arrows 375a, 380a, 385a and 390a represent different portions of light. Thus a portion 375a of light incident combination 300a penetrates to array 310a and is converted by the solar cells thereof to electrical energy, and a portion 380a passes through spacing 306a to element 350a, which reflects it towards back support panel 330a. A portion 385a passes to the cells of array 310a and is converted to electrical energy and a portion 390a passes to observer 370a, so that observer 370a distinguishes visually distinguishable feature 360a.

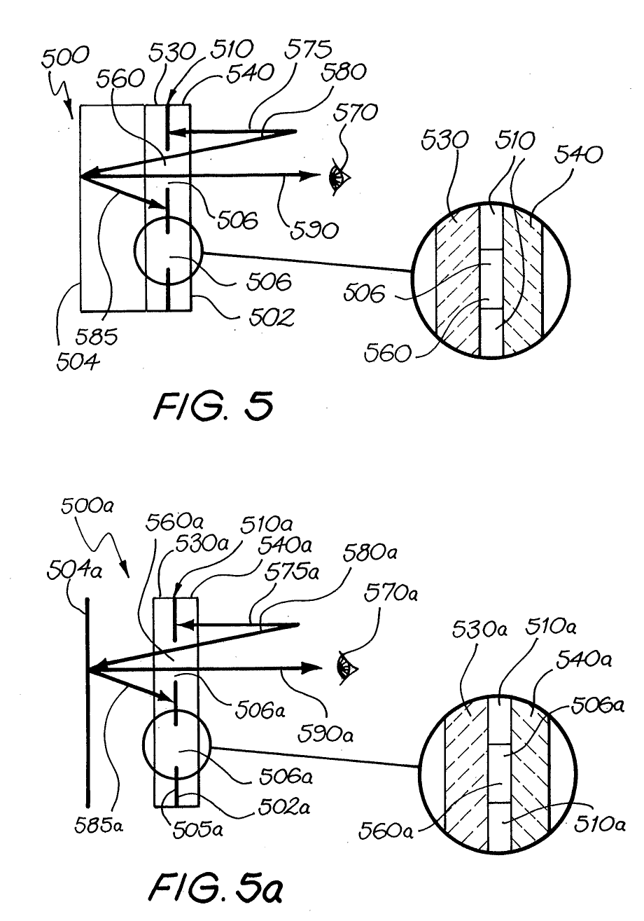

With reference to FIG. 4a, solar panel 400 has panel front 402 and a panel back 404, and comprises array 410 of solar cells, each of said solar cells having a front and a back, wherein the front and the back are each capable of converting at least a portion of solar light incident thereon into electrical energy, there being spacings 406 between the solar cells. Panel back 404 is a diffuse reflector. Element 460, which comprises a visually distinguishable feature, is located between panel back 404 and array 410. The visually distinguishable feature of element 460 is at least partially distinguishable through array 410 on viewing panel front 402. Array 410 is disposed between front support panel 440 and back support panel 430, said support panels being transparent. Observer 470 is capable of distinguishing the visually distinguishable feature of panel 460 through array 410. Arrows 475, 480, 485 and 490 represent different portions of light. Thus a portion 475 of light incident on panel front 402 penetrates to array 410 and is converted to electrical energy, and a portion 480 passes through spacing 406 and element 460 to panel back 404, which reflects it towards back support panel 430. A portion 485 passes to the cells of array 410 and is converted to electrical energy and a portion 490 passes to observer 470, so that observer 470 distinguishes the visually distinguishable feature of element 460.

With reference to FIG. 4b, solar panel 4100 has panel front 4102 and a panel back 4104, and comprises array 4110 of solar cells, each of said solar cells having a front and a back, wherein the front and the back are each capable of converting at least a portion of solar light incident thereon into electrical energy, there being spacings 4106 between the solar cells. Panel back 4104 is a diffuse reflector. Element 4160 is located between panel back 4104 and array 4110 and comprises activatable elements 4162, 4164 and 4166, which may be for example be LEDs. Elements 4162, 4164 and 4166 are capable of displaying a visually distinguishable feature which is at least partially distinguishable through array 4110 on viewing panel front 4102. The appearance of activatable elements 4162, 4164 and 4166 is capable of being changed by application of a stimulus, for example an electrical, thermal, optical or magnetic stimulus. For example they may be LEDs, the appearance of which is capable of being changed by application of an electrical stimulus. Array 4110 is disposed between front support panel 4140 and back support panel 4130, said support panels being transparent. Observer 4170 is capable of distinguishing the visually distinguishable feature of panel 4160 which is displayed by elements 4162, 4164 and 4166, through array 4110. Arrows 4175, 4180, 4185 and 4190 represent different portions of light. Thus a portion 4175 of light incident on panel front 4102 penetrates to array 4110 and is converted to electrical energy, and a portion 4180 passes through spacing 4106 and element 4160 to panel back 4104, which reflects it towards back support panel 4130. A portion 4185 passes to the cells of array 4110 and is converted to electrical energy and a portion 4190 passes to observer 4170, so that observer 4170 distinguishes the visually distinguishable feature of element 4160. In order to change the appearance of the visually distinguishable feature, the stimuli applied to activatable elements 4162, 4164 and 4166 is changed. For example if elements 4162, 4164 and 4166 are LEDs, the appearance may be changed by changing the electrical stimuli applied to them.

With reference to FIG. 4c, combination 400c for conversion of solar energy comprises array 410c of solar cells, each of said solar cells having a front and a back, wherein the front and the back are each capable of converting at least a portion of solar light incident thereon into electrical energy, there being spacings 406c between the solar cells. Array 410c has array front 402c and array back 405c. Diffuse reflector 404c is provided to reflect light towards array 410c. Element 460c is transparent and comprises a visually distinguishable feature, and is located between reflector 404c and array 410c. The visually distinguishable feature of element 460c is at least partially distinguishable through array 410c on viewing combination 400c. Array 410c is disposed between front support panel 440c and back support panel 430c, said support panels being transparent. Observer 470c is capable of distinguishing the visually distinguishable feature of panel 460c through array 410c. Arrows 475c, 480c, 485c and 490c represent different portions of light. Thus a portion 475c of light incident on combination 400c penetrates to array 410c and is converted to electrical energy, and a portion 480c passes through spacing 406c and element 460c to reflector 404c, which reflects it towards back support panel 430c. A portion 485c passes to the cells of array 410c and is converted to electrical energy and a portion 490c passes to observer 470c, so that observer 470c distinguishes the visually distinguishable feature of element 460c.

With reference to FIG. 4d, combination 4100d for conversion of solar energy comprises array 4110d of solar cells, each of said solar cells having a front and a back, wherein the front and the back are each capable of converting at least a portion of solar light incident thereon into electrical energy, there being spacings 4106d between the solar cells. Array 4110d has array front 4102d and array back 4105d. Diffuse reflector 4104d is provided to reflect light towards array 4110d. Element 4160d is transparent and comprises activatable elements 4162d, 4164d and 4166d, which may be for example be LEDs. Element 4160d is located between reflector 4104d and array 4110d. Activatable elements 4162d, 4164d and 4166d are capable of displaying a visually distinguishable feature which is at least partially distinguishable through array 4110d on viewing combination 4100d. The appearance of activatable elements 4162d, 4164d and 4166d is capable of being changed by application of a stimulus, for example an electrical, thermal, optical or magnetic stimulus. For example they may be LEDs, the appearance of which is capable of being changed by application of an electrical stimulus. Array 4110d is disposed between front support panel 4140d and back support panel 4130d, said support panels being transparent. Observer 4170d is capable of distinguishing the visually distinguishable feature of panel 4160d which is displayed by elements 4162d, 4164d and 4166d, through array 4110d. Arrows 4175d, 4180d, 4185d and 4190d represent different portions of light. Thus a portion 4175d of light incident on combination 4100d penetrates to array 4110d and is converted to electrical energy, and a portion 4180d passes through spacing 4106d and element 4160d to reflector 4104d, which reflects it towards back support panel 4130d. A portion 4185d passes to the cells of array 4110d and is converted to electrical energy and a portion 4190d passes to observer 4170d, so that observer 4170d distinguishes the visually distinguishable feature of element 4160d. In order to change the appearance of the visually distinguishable feature, the stimuli applied to activatable elements 4162d, 4164d and 4166d is changed. For example if elements 4162d, 4164d and 4166d are LEDs, the appearance may be changed by changing the electrical stimuli applied to them.

With reference to FIG. 5, solar panel 500 has panel front 502 and a panel back 504, and comprises array 510 of solar cells, each of said solar cells having a front and a back, wherein the front and the back are each capable of converting at least a portion of solar light incident thereon into electrical energy, there being spacings 506 between the solar cells. Panel back 504 is a diffuse reflector. Element 560 comprises an encapsulant, and is located between the solar cells of array 510, in spacings 506. The encapsulant comprises transparent coloured material having different colours in different regions of array 510, and thereby embodies a visually distinguishable feature. Array 510 is disposed between front support panel 540 and back support panel 530, said support panels being transparent. Observer 570 is capable of distinguishing the visually distinguishable feature of element 560. Arrows 575, 580, 585 and 590 represent different portions of light. Thus a portion 575 of light incident on panel front 502 penetrates to array 510 and is converted to electrical energy, and a portion 580 passes through spacing 506 to panel back 504, which reflects it towards back support panel 530. A portion 585 passes to the cells of array 510 and is converted to electrical energy and a portion 590 passes to observer 570, so that observer 570 distinguishes the visually distinguishable feature of element 560.

With reference to FIG. 5a, combination 500a for conversion of solar energy comprises array 510a of solar cells, each of said solar cells having a front and a back, wherein the front and the back are each capable of converting at least a portion of solar light incident thereon into electrical energy, there being spacings 506a between the solar cells. Array 510a has array front 502a and array back 505a. Diffuse reflector 504a is provided to reflect light towards array 510a. Element 560a comprises an encapsulant, and is located between the solar cells of array 510a, in spacings 506a. The encapsulant comprises transparent coloured material having different colours in different regions of array 510a, and thereby embodies a visually distinguishable feature. Array 510a is disposed between front support panel 540a and back support panel 530a, said support panels being transparent. Observer 570a is capable of distinguishing the visually distinguishable feature of element 560. Arrows 575a, 580a, 585a and 590a represent different portions of light. Thus a portion 575a of light incident on combination 500a penetrates to array 510a and is converted to electrical energy, and a portion 580a passes through spacing 506a to reflector 504a, which reflects it towards back support panel 530a. A portion 585a passes to the cells of array 510a and is converted to electrical energy and a portion 590a passes to observer 570a, so that observer 570a distinguishes the visually distinguishable feature of element 560a.

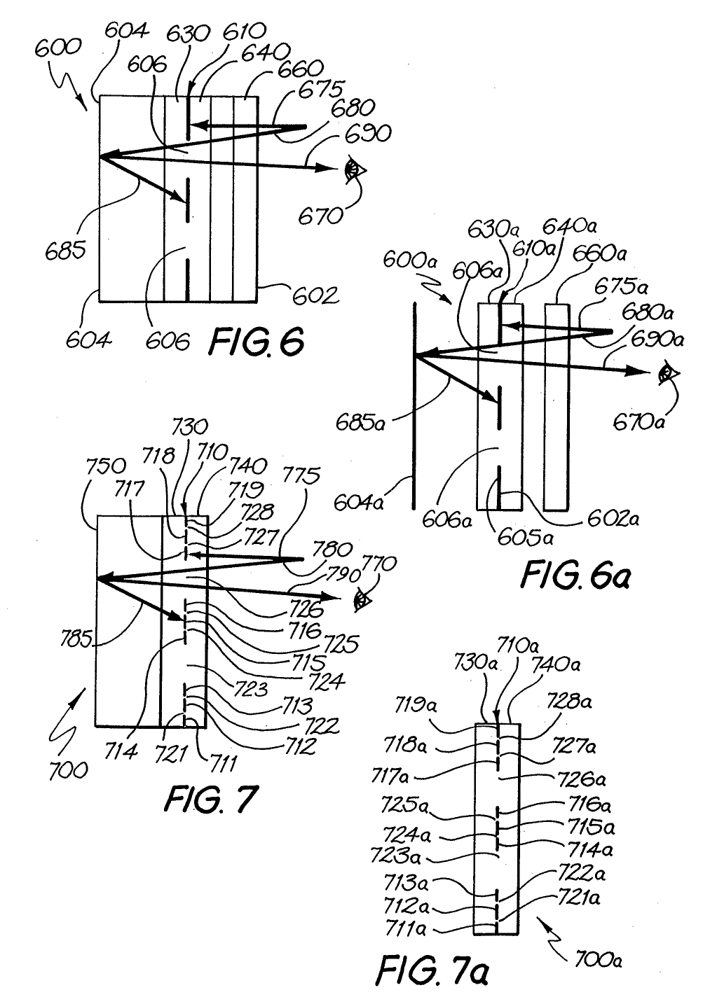

With reference to FIG. 6, solar panel 600 has panel front 602 and a panel back 604, and comprises array 610 of solar cells, each of said solar cells having a front and a back, wherein the front and the back are each capable of converting at least a portion of solar light incident thereon into electrical energy, there being spacings 606 between the solar cells. Panel back 604 is a diffuse reflector. Panel front 602 comprises element 660, which has a visually distinguishable feature, said feature being such that it does not completely prevent solar light incident on panel front 602 from being incident on at least a portion of array 610. Array 610 is disposed between front support panel 640 and back support panel 630, said support panels being transparent. Observer 670 is capable of distinguishing the visually distinguishable feature of panel 660. Arrows 675, 680, 685 and 690 represent different portions of light. Thus a portion 675 of light incident on panel front 602 penetrates to array 610 and is converted to electrical energy, and a portion 680 passes through spacing 606 to panel back 604, which reflects it towards back support panel 630. A portion 685 passes to the cells of array 610 and is converted to electrical energy and a portion 690 passes through element 660 to observer 670, so that observer 670 distinguishes the visually distinguishable feature of element 660.

With reference to FIG. 6a, combination 600a for conversion of solar energy comprises array 610a of solar cells, each of said solar cells having a front and a back, wherein the front and the back are each capable of converting at least a portion of solar light incident thereon into electrical energy, there being spacings 606a between the solar cells. Array 610a has array front 602a and array back 605a. Diffuse reflector 604a is provided to reflect light towards array 610a. Element 660a is transparent and has a visually distinguishable feature, said feature being such that it does not completely prevent solar light incident on element 660a from being incident on at least a portion of array 610a. Array 610a is disposed between front support panel 640a and back support panel 630a, said support panels being transparent. Observer 670a is capable of distinguishing the visually distinguishable feature of panel 660a. Arrows 675a, 680a, 685a and 690a represent different portions of light. Thus a portion 675a of light incident on combination 600a penetrates to array 610a and is converted to electrical energy, and a portion 680a passes through spacing 606a to reflector 604a, which reflects it towards back support panel 630a. A portion 685a passes to the cells of array 610a and is converted to electrical energy and a portion 690a passes through element 660a to observer 670a, so that observer 670a distinguishes the visually distinguishable feature of element 660a.

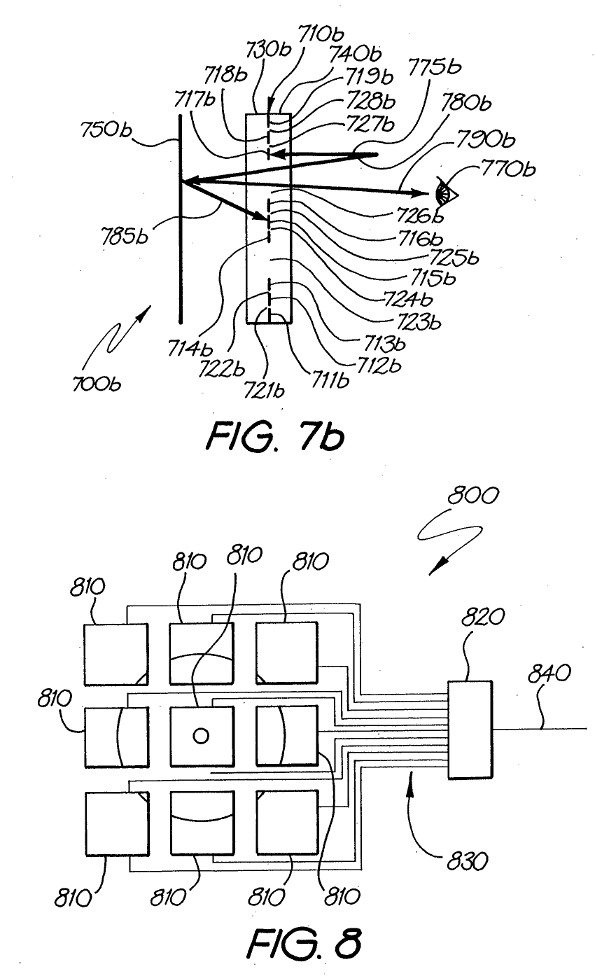

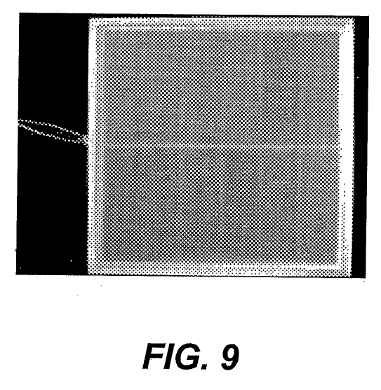

With reference to FIG. 7, solar panel 700 comprises an array 710 of solar cells 711, 712, 713, 714, 715, 716, 717, 718 and 719, each of said solar cells having a front and a back, wherein the front and the back are each capable of converting at least a portion of solar light incident thereon into electrical energy. Array 710 is disposed between front support panel 740 and back support panel 730, said support panels being transparent. There are spacings 721, 722, 723, 724, 725, 726, 727 and 728 between solar cells 711 and 712, 712 and 713, 713 and 714, 714 and 715, 715 and 716, 716 and 717, 717 and 718, and 718 and 719 respectively. The arrangement of solar cells 711, 712, 713, 714, 715, 716, 717, 718 and 719 in array 710 embodies a visually distinguishable feature. Thus, since solar cells appear dark, the regions of array 710 with spacings 721 and 722, and with spacings 724 and 725, and with spacings 727 and 728, which are relatively small spacings, appear relatively dark, and the regions of array 710 with spacings 723 and 726, which are relatively large spacings, appear relatively pale. The arrangement of relatively pale and relatively dark regions embodies a visually distinguishable feature. Observer 770 is capable of distinguishing the visually distinguishable feature embodied in the arrangement of solar cells 711 to 719. Diffuse reflector 750 is located so that it is capable of reflecting at least part of the solar light incident thereon towards at least some of the solar cells of array 710. Arrows 775, 780, 785 and 790 represent different portions of light. Thus a portion 775 of light incident on panel 740 penetrates to array 710 and is converted to electrical energy, and a portion 780 passes through spacing 726 to reflector 750, which reflects it towards panel 730. A portion 785 passes to the cells of array 710 and is converted to electrical energy and a portion 790 passes to observer 770, so that observer 770 distinguishes the visually distinguishable feature embodied in the arrangement of solar cells 711 to 719.

With reference to FIG. 7a, solar panel 700a comprises an array 710a of solar cells 711a, 712a, 713a, 714a, 715a, 716a, 717a, 718a and 719a, each of said solar cells having a front and a back, wherein at least the front is capable of converting at least a portion of solar light incident thereon into electrical energy. Array 710a is disposed between front support panel 740a and back support panel 730a, said support panels being transparent. There are spacings 721a, 722a, 723a, 724a, 725a, 726a, 727a and 728a between solar cells 711a and 712a, 712a and 713a, 713a and 714a, 714a and 715a, 715a and 716a, 716a and 717a, 717a and 718a, and 718a and 719a respectively. The arrangement of solar cells 711a, 712a, 713a, 714a, 715a, 716a, 717a, 718a and 719a in array 710a embodies a visually distinguishable feature. Thus, since solar cells appear dark, the regions of array 710a with spacings 721a and 722a, and with spacings 724a and 725a, and with spacings 727a and 728a, which are relatively small spacings, appear relatively dark, and the regions of array 710a with spacings 723a and 726a, which are relatively large spacings, appear relatively pale. The arrangement of relatively pale and relatively dark regions embodies a visually distinguishable feature. An observer is capable of distinguishing the visually distinguishable feature embodied in the arrangement of solar cells 711a to 719a, and may also be capable of distinguish a visually distinguishable feature located on the other side of solar panel 700a from the observer.

With reference to FIG. 7b, combination 700b for conversion of solar energy comprises an array 710b of solar cells 711b, 712b, 713b, 714b, 715b, 716b, 717b, 718b and 719b, each of said solar cells having a front and a back, wherein the front and the back are each capable of converting at least a portion of solar light incident thereon into electrical energy. Array 710b is disposed between front support panel 740b and back support panel 730b, said support panels being transparent. There are spacings 721b, 722b, 723b, 724b, 725b, 726b, 727b and 728b between solar cells 711b and 712b, 712b and 713b, 713b and 714b, 714b and 715b, 715b and 716b, 716b and 717b, 717b and 718b, and 718b and 719b respectively. The arrangement of solar cells 711b, 712b, 713b, 714b, 715b, 716b, 717b, 718b and 719b in array 710b embodies a visually distinguishable feature. Thus, since solar cells appear dark, the regions of array 710b with spacings 721b and 722b, and with spacings 724b and 725b, and with spacings 727b and 728b, which are relatively small spacings, appear relatively dark, and the regions of array 710b with spacings 723b and 726b, which are relatively large spacings, appear relatively pale. The arrangement of relatively pale and relatively dark regions embodies a visually distinguishable feature. Observer 770b is capable of distinguishing the visually distinguishable feature embodied in the arrangement of solar cells 711b to 719b. Diffuse reflector 750b is located so that it is capable of reflecting at least part of the solar light incident thereon towards at least some of the solar cells of array 710b. Arrows 775b, 780b, 785b and 790b represent different portions of light. Thus a portion 775b of light incident on panel 740b penetrates to array 710b and is converted to electrical energy, and a portion 780b passes through spacing 726b to reflector 750b, which reflects it towards panel 730b. A portion 785b passes to the cells of array 710b and is converted to electrical energy and a portion 790b passes to observer 770b, so that observer 770b distinguishes the visually distinguishable feature embodied in the arrangement of solar cells 711b to 719b.

FIG. 8 shows a plurality of solar panels according to the present invention wherein the solar panels combine to display a single visually distinguishable feature. Each of panels 800 has an element having a visually distinguishable feature which is capable of being altered electronically. The element may be for example an array of LEDs. With reference to FIG. 8, display unit 800 comprises panels 810 connected to control unit 820 by output cables 830. Control unit 820 also has input cable 840 for receiving an input signal. Alternatively control unit 820 may be fitted with a wireless receiver for receiving the input signal. In a further alternative, each of panels 810 may be fitted with wireless receivers and control unit may have a wireless transmitter for sending signals to panels 810. In operation, an input signal is received by control unit 820 through input cable 840. The input signal may be a digitised image signal representing an image to be displayed on display unit 800. Control unit 820 processes the input signal to generate a plurality of output signals, one corresponding to each of panels 810. The output signals are then sent to the corresponding panels 810 through output cables 830. Panels 810 convert the output signals to individual images which are displayed on panels 810 in such a way that the images provide a single composite visually distinguishing feature. In FIG. 8, 9 panels are shown. However it will be readily apparent that a large number of panels (e.g. up to multiple thousands of panels) maybe used, and the display unit may be capable of displaying highly complex and rapidly changing images, as for example, a large video screen image or television image.

FIG. 9 shows a photograph of a solar panel according to the present invention.

### EXAMPLE

A solar panel was constructed with the following specifications: Aperture area 1185 cm²2×6 strings of 88 series-connected Sliver® solar cells.

Each Sliver® cell was 1 mm×57 mm and about 65 micron thick. The Sliver® cells were bi-facial (i.e. capable of collecting light on either side).

Surface coverage of solar cells was 50%, ie there was a 1 mm gap between each solar cell.

The solar cells were mounted between two panes of glass, the front pane being about 1 mm thick and the back pane being about 3 mm thick. The cells were encapsulated in an EVA encapsulant. Behind the back pane of glass was located a reflector of coloured paper (“Reflex” copy paper) as specified in Table 1. The logo was a reasonably bright pale poster. There was an air gap between the glass and the paper of about 0.1 mm.

Results for solar light collection are shown in Table 1.

TABLE 1

| | Voc | Isc | nVoc | nIsc | nVmp | nImp |
|---|---|---|---|---|---|---|
| Test | (V) | (mA) | (V) | (mA) | (V) | (mA) |
| Parallel White | 56.90 | −382.81 | 58.13 | −335.93 | 47.14 | −296.14 |
| Parallel Black | 56.64 | −269.32 | 57.87 | −236.38 | 47.15 | −213.67 |
| Yellow Back | 56.88 | −372.10 | 58.12 | −325.42 | 46.89 | −289.07 |
| Green Back | 56.85 | −360.29 | 58.08 | −315.09 | 46.14 | −284.74 |
| Blue Back | 56.73 | −356.27 | 57.96 | −311.57 | 46.65 | −277.82 |
| Pink Back | 56.88 | −373.09 | 58.11 | −326.29 | 46.39 | −292.53 |
| Orange Back | 56.83 | −369.13 | 58.06 | −322.82 | 46.64 | −288.20 |
| Red Back | 56.64 | −350.10 | 57.87 | −308.02 | 46.65 | −275.13 |
| Logo | 56.50 | −364.18 | 57.73 | −319.83 | 46.40 | −285.94 |

| Test | FF | Ref | Temp | Eff |
|---|---|---|---|---|
| Parallel White | 71.49% | 166.8 | 33.8 | 11.78% |
| Parallel Black | 73.65% | 166.8 | 33.8 | 8.50% |
| Yellow Back | 71.67% | 167.4 | 33.8 | 11.44% |
| Green Back | 71.79% | 167.4 | 33.8 | 11.09% |
| Blue Back | 71.77% | 167.4 | 33.8 | 10.94% |
| Pink Back | 71.57 | 167.4 | 33.8 | 11.45% |
| Orange Back | 71.72 | 167.4 | 33.8 | 11.34% |
| Red Back | 72.00 | 166.4 | 33.8 | 10.83% |
| Logo | 71.86 | 166.7 | 33.8 | 11.20% |

In Table 1, abbreviations used are:

| | |
|---|---|
| Voc: | Open-Circuit Voltage (in Volts) |
| Isc: | Short-Circuit Current (mostly proportional to the light |
| | intensity) (in milliamperes) |
| nVoc: | Normalised Voc, i.e. Open-Circuit Voltage corrected for |
| | 25° C. reference. The Temperature Coefficient of the Voc |
| | is negative, which means that at the measurement temperature |
| | (about 30° C. to 33° C.), the voltage is lower than the |
| | Standard Rating Conditions (25° C.) voltage. |
| nIsc: | Normalised Short-Circuit Current, corrected for intensity |
| | of light to the Standard Rating Conditions of 1000 Watt/m² |
| nVmp: | Normalised “Maximum Power Point” Voltage |
| nImp: | Normalised “Maximum Power Point” Current |
| FF: | Fill Factor = ration of (nImp * nVmp)/(nIsc * nVoc), |
| | measures the “squareness” of the current-voltage |
| | characteristics |
| Ref: | measured short-circuit current of a reference calibrated |
| | solar cell or other light intensity measurement device |
| Temp: | temperature of the module during measurement |
| Eff: | efficiency (under Standard Rating Conditions, i.e. 1000 |
| | Watt/m² and 25 C.) |

Values should be taken as relative values and need to be referenced to the numbers for the “Parallel White” (with White paper). Since the experiment deals with relative light intensity on the solar cells, the significant parameters are “Nisc” and “Eff”. Even with Red paper (which should be the worst case after Black paper), the short-circuit current was still more than 90% of the short-circuit current with the white paper. The Black paper gave a short-circuit current of 70% of the short-circuit current with the white paper. All the other colours gave a nlsc greater than 90% of the nIsc of the white paper.

### Comparative Example

The back surface of the back pane of glass of the solar panel of the above example was then painted with white paint to form a Lambertian reflector optically coupled to the panel. Results are shown in Table 2.

TABLE 2

| Test | Voc(V) | Isc(mA) | nVoc(V) | nIsc(mA) | nVmp(V) | nImp(mA) |
|---|---|---|---|---|---|---|
| lp | 57.81 | −195.95 | 58.75 | −186.40 | 46.64 | −167.57 |
| rp | 57.86 | −196.94 | 58.98 | −187.10 | 47.78 | −163.59 |
| pp | 57.68 | −393.87 | 59.00 | −371.06 | 47.20 | −326.31 |

| Test | FF | Ref | Temp | Eff |
|---|---|---|---|---|
| lp | 71.02% | 153.9 | 30.5 | 13.2% |
| rp | 70.42% | 154.1 | 31.6 | 13.2% |
| pp | 70.35% | 155.4 | 32.8 | 13.0% |

The same abbreviations are used for Table 2 as for Table 1, as well as the following:

| | |
|---|---|
| lp: | left panel |
| rp | right panel |
| pp | parallel (ie both) panels |

It should be noted that the current for the pp case is approximately double that of the lp and rp cases, since the area is approximately double, however the voltages are about the same, since the intensity of incident light is about the same. The efficiency of the solar panel of the comparative example is slightly higher than that of the example of Table 1, since the reflector is optically coupled to the back panel.

1. A solar panel having a panel front and a panel back comprising:
an array of solar cells, each of said solar cells having a front and a back, wherein at least the front is capable of converting at least a portion of solar light incident thereon into electrical energy, there being spacings between at least some of the solar cells; and
an element comprising a visually distinguishable feature at at least one position selected from the group consisting of: between the panel back and the panel front, on the panel front, on the panel back, at the panel front, and at the panel back,
such that the visually distinguishable feature is at least partially distinguishable on viewing the panel front, and wherein the nature of the visually distinguishable feature and the location of the element relative to the solar cells do not completely prevent solar light incident on the panel front from being incident on at least a portion of the array.

2. The solar panel of claim 1 wherein the nature of the visually distinguishable feature and the location of the element relative to the solar cells are such that the amount of solar light incident on the array relative to the amount of solar light incident on the panel front is greater than about 50%.

3. The solar panel of claim 1 wherein the element is removable from the solar panel.

4. The solar panel of claim 1 in which there is an encapsulant between the solar cells.

5. The solar panel of claim 4 wherein the encapsulant is at least partially transparent.

6. The solar panel of claim 1 wherein the array is disposed on a transparent support panel.

7. The solar panel of claim 1 wherein the array is disposed between transparent support panels.

8. The solar panel of claim 1 wherein the backs of at least some of the solar cells are capable of converting at least a portion of solar light incident thereon into electrical energy, and there is a reflector located between the array and the panel back, said reflector being capable of reflecting at least part of the solar light incident on the solar panel towards the backs of at least some of the solar cells.

9. The solar panel of claim 1 wherein the backs of at least some of the solar cells are capable of converting at least a portion of solar light incident thereon into electrical energy and the panel back comprises a reflector, said reflector being capable of reflecting at least part of the solar light incident on the solar panel towards the backs of at least some of the solar cells.

10. The solar panel of claim 9 wherein the reflector is selected from the group consisting of a Lambertian reflector, a diffuse reflector, a light scattering reflector and a reflector that approximates one of these.

11. The solar panel of claim 1 wherein the visually distinguishable feature is at least partially distinguishable through the array on viewing a component selected from the group consisting of the panel front or the panel back.

12. The solar panel of claim 1 wherein the element is located between the solar cells of the array.

13. The solar panel of claim 12 wherein the element comprises an encapsulant.

14. The solar panel of claim 1 wherein the element is located between the array and the panel front.

15. The solar panel of claim 1 wherein the panel front comprises the element.

16. The solar panel of claim 1 wherein the element comprises at least one activatable element, the appearance of which is capable of being changed by application of a stimulus selected from the group consisting of electrical, thermal, optical or magnetic stimuli.

17. The solar panel of claim 16 wherein the stimulus is supplied from a source selected from the group consisting of a source external to the solar panel and the array of solar cells.

18. The solar panel of claim 1 wherein the visually distinguishable feature is capable of being changed electronically.

19. The solar panel of claim 1 additionally comprising means to change the visually distinguishable feature, said means being selected from the group consisting of means to change the visually distinguishable feature physically, mechanically, electrically, thermally, optically and magnetically.

20. A solar panel comprising an array of solar cells, each of said solar cells having a front and a back, wherein at least the front is capable of converting at least a portion of solar light incident thereon into electrical energy, and wherein there are spacings between at least some of the solar cells whereby the arrangement of the solar cells in the array embodies a visually distinguishable feature.

21. The solar panel of claim 1 wherein each of said solar cells comprises:
a semiconductor strip comprising a p-type dopant or an n-type dopant and having a front, a back, a first side surface and a second side surface, wherein, in the event that the semiconductor strip comprises a p-type dopant, a first diffusion layer of an n-type conductivity has been introduced by diffusion, using a suitable dopant, into at least a portion of the front and at least a portion of the first side surface and, in the event that the semiconductor strip comprises an n-type dopant, a first diffusion layer of a p-type conductivity has been introduced by diffusion, using a suitable dopant, into at least a portion of the front surface and at least a portion of the first side surface;
a first metal contact in electrical contact with the first diffusion layer of the first side surface; and
a second metal contact in electrical contact with the second side surface but being electrically isolated from the first diffusion layer.

22. A combination for conversion of solar energy comprising:
an array of solar cells, each of said solar cells having a front and a back, wherein at least the front is capable of converting at least a portion of solar light incident thereon into electrical energy, there being spacings between at least some of the solar cells, and said array having an array front and an array back, and
an element comprising a visually distinguishable feature at at least one position selected from the group consisting of in front of the array front, at the array front, at the array back or behind the array back,
such that the visually distinguishable feature is at least partially distinguishable on viewing the combination, and wherein the nature of the visually distinguishable feature and the location of the element relative to the solar cells do not completely prevent solar light incident on the combination from being incident on at least a portion of the array.

23. The combination of claim 22 wherein each of said solar cells comprises:
a semiconductor strip comprising a p-type dopant or an n-type dopant and having a front, a back, a first side surface and a second side surface, wherein, in the event that the semiconductor strip comprises a p-type dopant, a first diffusion layer of an n-type conductivity has been introduced by diffusion, using a suitable dopant, into at least a portion of the front and at least a portion of the first side surface and, in the event that the semiconductor strip comprises an n-type dopant, a first diffusion layer of a p-type conductivity has been introduced by diffusion, using a suitable dopant, into at least a portion of the front surface and at least a portion of the first side surface;
a first metal contact in electrical contact with the first diffusion layer of the first side surface; and
a second metal contact in electrical contact with the second side surface but being electrically isolated from the first diffusion layer.

24. A process for making a solar panel having a panel front and a panel back, said process comprising locating:
an array of solar cells, each of said solar cells having a front and a back, wherein at least the front is capable of converting at least a portion of solar light incident thereon into electrical energy, there being spacings between at least some of the solar cells, and
an element comprising a visually distinguishable feature,
such that the element is located at at least one position selected from the group consisting of between the panel back and the panel front, on the panel front, on the panel back, at the panel front, and at the panel back, and such that the visually distinguishable feature is at least partially distinguishable on viewing the panel front, and wherein the nature of the visually distinguishable feature and the location of the visually distinguishable feature relative to the solar cells do not completely prevent solar light incident on the panel front from being incident on at least a portion of the array.

25. A process for making a solar panel comprising the step of arranging a plurality of solar cells in an array, each of said solar cells having a front and a back, wherein at least the front is capable of converting at least a portion of solar light incident thereon into electrical energy, and wherein there are spacings between at least some of the solar cells whereby the arrangement of the solar cells in the array embodies a visually distinguishable feature.

26. The process of claim 25 additionally comprising the step of locating the solar panel and a reflector such that the reflector is capable of reflecting at least part of the solar light incident on the solar panel towards at least some of the solar cells of the array.

27. The process of claim 24 wherein each of said solar cells comprises:
a semiconductor strip comprising a p-type dopant or an n-type dopant and having a front, a back, a first side surface and a second side surface, wherein, in the event that the semiconductor strip comprises a p-type dopant, a first diffusion layer of an n-type conductivity has been introduced by diffusion, using a suitable dopant, into at least a portion of the front and at least a portion of the first side surface and, in the event that the semiconductor strip comprises an n-type dopant, a first diffusion layer of a p-type conductivity has been introduced by diffusion, using a suitable dopant, into at least a portion of the front surface and at least a portion of the first side surface;
a first metal contact in electrical contact with the first diffusion layer of the first side surface; and
a second metal contact in electrical contact with the second side surface but being electrically isolated from the first diffusion layer.

28. A solar panel when made by the process of claim 24.

29. A process for making a combination for conversion of solar energy, said process comprising locating:
an array of solar cells, each of said solar cells having a front and a back, wherein at least the front is capable of converting at least a portion of solar light incident thereon into electrical energy, there being spacings between at least some of the solar cells, and said array having an array front and an array back, and
an element comprising a visually distinguishable feature,
such that the element is located at at least one position selected from the group consisting of in front of the array front, at the array front, at the array back or behind the array back, and such that the visually distinguishable feature is at least partially distinguishable on viewing the panel front, wherein the nature of the visually distinguishable feature and the location of the visually distinguishable feature relative to the solar cells do not completely prevent solar light incident on the combination from being incident on at least a portion of the array.

30. The process of claim 29 wherein each of said solar cells comprises:
a semiconductor strip comprising a p-type dopant or an n-type dopant and having a front, a back, a first side surface and a second side surface, wherein, in the event that the semiconductor strip comprises a p-type dopant, a first diffusion layer of an n-type conductivity has been introduced by diffusion, using a suitable dopant, into at least a portion of the front and at least a portion of the first side surface and, in the event that the semiconductor strip comprises an n-type dopant, a first diffusion layer of a p-type conductivity has been introduced by diffusion, using a suitable dopant, into at least a portion of the front surface and at least a portion of the first side surface;
a first metal contact in electrical contact with the first diffusion layer of the first side surface; and
a second metal contact in electrical contact with the second side surface but being electrically isolated from the first diffusion layer.

31. A combination for conversion of solar energy, when made by the process of claim 29.

32. A solar cell having a front and a back, wherein at least the front is capable of converting at least a portion of solar light incident thereon into electrical energy, when used in a solar panel according to claim 1.

33. An array of solar cells, each of which has a front and a back, wherein at least the front is capable of converting at least a portion of solar light incident thereon into electrical energy, when used in a solar panel according to claim 1.

34. An array of solar cells when used in a solar panel according to claim 1, wherein each of said solar cells comprises:
a semiconductor strip comprising a p-type dopant or an n-type dopant and having a front, a back, a first side surface and a second side surface, wherein, in the event that the semiconductor strip comprises a p-type dopant, a first diffusion layer of an n-type conductivity has been introduced by diffusion, using a suitable dopant, into at least a portion of the front and at least a portion of the first side surface and, in the event that the semiconductor strip comprises an n-type dopant, a first diffusion layer of a p-type conductivity has been introduced by diffusion, using a suitable dopant, into at least a portion of the front surface and at least a portion of the first side surface;
a first metal contact in electrical contact with the first diffusion layer of the first side surface; and
a second metal contact in electrical contact with the second side surface but being electrically isolated from the first diffusion layer.

35. Use of a solar panel according to claim 1 for converting light into electrical energy.

36. A method for converting light into electrical energy comprising exposing a solar panel according to claim 1 to the light such that at least a portion of the light is incident on the panel front.

37. A solar panel according to claim 1 when used for converting light into electrical energy.

38. The solar panel of claim 8 wherein the reflector is selected from the group consisting of a Lambertian reflector, a diffuse reflector, a light scattering reflector and a reflector that approximates one of these.

39. The solar panel of claim 20 wherein each of said solar cells comprises:
a semiconductor strip comprising a p-type dopant or an n-type dopant and having a front, a back, a first side surface and a second side surface, wherein, in the event that the semiconductor strip comprises a p-type dopant, a first diffusion layer of an n-type conductivity has been introduced by diffusion, using a suitable dopant, into at least a portion of the front and at least a portion of the first side surface and, in the event that the semiconductor strip comprises an n-type dopant, a first diffusion layer of a p-type conductivity has been introduced by diffusion, using a suitable dopant, into at least a portion of the front surface and at least a portion of the first side surface;
a first metal contact in electrical contact with the first diffusion layer of the first side surface; and
a second metal contact in electrical contact with the second side surface but being electrically isolated from the first diffusion layer.

40. The process of claim 25 wherein each of said solar cells comprises:
a semiconductor strip comprising a p-type dopant or an n-type dopant and having a front, a back, a first side surface and a second side surface, wherein, in the event that the semiconductor strip comprises a p-type dopant, a first diffusion layer of an n-type conductivity has been introduced by diffusion, using a suitable dopant, into at least a portion of the front and at least a portion of the first side surface and, in the event that the semiconductor strip comprises an n-type dopant, a first diffusion layer of a p-type conductivity has been introduced by diffusion, using a suitable dopant, into at least a portion of the front surface and at least a portion of the first side surface;
a first metal contact in electrical contact with the first diffusion layer of the first side surface; and
a second metal contact in electrical contact with the second side surface but being electrically isolated from the first diffusion layer.

41. A solar panel when made by the process of claim 25.

42. A solar cell having a front and a back, wherein at least the front is capable of converting at least a portion of solar light incident thereon into electrical energy, when used in a solar panel according to claim 20.

43. An array of solar cells, each of which has a front and a back, wherein at least the front is capable of converting at least a portion of solar light incident thereon into electrical energy, when used in a solar panel according to claim 20.

44. An array of solar cells when used in a solar panel according to claim 20, wherein each of said solar cells comprises:
a semiconductor strip comprising a p-type dopant or an n-type dopant and having a front, a back, a first side surface and a second side surface, wherein, in the event that the semiconductor strip comprises a p-type dopant, a first diffusion layer of an n-type conductivity has been introduced by diffusion, using a suitable dopant, into at least a portion of the front and at least a portion of the first side surface and, in the event that the semiconductor strip comprises an n-type dopant, a first diffusion layer of a p-type conductivity has been introduced by diffusion, using a suitable dopant, into at least a portion of the front surface and at least a portion of the first side surface;
a first metal contact in electrical contact with the first diffusion layer of the first side surface; and
a second metal contact in electrical contact with the second side surface but being electrically isolated from the first diffusion layer.

45. Use of a solar panel according to claim 20 for converting light into electrical energy.

46. A method for converting light into electrical energy comprising exposing a solar panel according to claim 20 to the light such that at least a portion of the light is incident on the panel front.

47. A solar panel according to claim 20 when used for converting light into electrical energy.
